(19) United States
(12) Patent Application Publication
(10) Pub. No.: US 2026/0204193 A1
(43) Pub. Date: Jul. 16, 2026

(54) DISPLAY APPARATUS INCLUDING TEST POINTS AND ELECTRONIC APPARATUS INCLUDING THE DISPLAY APPARATUS

(71) Applicant: SAMSUNG DISPLAY CO., LTD., YONGIN-SI (KR)

(72) Inventor: DONGBEOM CHO, Yongin-si (KR)

(21) Appl. No.: 19/350,390

(22) Filed: Oct. 6, 2025

(30) Foreign Application Priority Data
Jan. 15, 2025 (KR) 10-2025-0005834

(51) Int. Cl. G09G 3/00; G01R 31/28; G09G 3/20; H10D 86/40

(52) U.S. Cl. CPC G09G 3/006; G01R 31/282; G09G 3/2092; H10D 86/441; G09G 3/035; G09G 2330/12

(57) ABSTRACT

A display apparatus includes a display panel and a printed circuit board. The display panel includes including an active area configured to display an image, a bending area in which a substrate of the display panel is bent, a bonding area in which a printed circuit board is bonded to the display panel, and a crack test area including a test pattern. The printed circuit board is bonded at the bonding area of the display panel. The printed circuit board includes a plurality of test points. The test points, the printed circuit board, the bonding area, the bending area, and the crack test area form a test path.

### CROSS-REFERENCE TO RELATED APPLICATION

This U.S. non-provisional patent application claims priority under 35 U.S.C. § 119 to Korean Patent Application No. 10-2025-0005834, filed on January 15, 2025, in the Korean Intellectual Property Office (KIPO), the entire disclosure of which is incorporated by reference herein.

### TECHNICAL FIELD

Embodiments of the present inventive concept relate to a display apparatus and, more particularly to, a display apparatus including test points and an electronic apparatus including the display apparatus.

### Discussion of the Related Art

A display apparatus includes a display panel and a display panel driver. In some cases, the display panel includes a plurality of gate lines, a plurality of data lines, a plurality of emission lines and a plurality of pixels. The display panel driver includes a gate driver, a data driver, an emission driver and a driving controller. The gate driver outputs gate signals to the gate lines. The data driver outputs data voltages to the data lines. The emission driver outputs emission signals to the emission lines. The driving controller controls the gate driver, the data driver, the emission driver, and other associated components.

When a crack occurs in a portion of the display panel, moisture may penetrate into the interior of the display apparatus through the crack. In addition, physical deformation such as shrinkage or delamination of the display apparatus may occur.

When the cracks of the display panel are not detected, a defective product might not be filtered out during inspection or quality control.

### SUMMARY

Embodiments of the present inventive concept provide a display apparatus for determining a crack of a display panel using an auto resistance test method.

Embodiments of the present inventive concept provide an electronic apparatus including the display apparatus.

In an embodiment of the present inventive concept, the display apparatus includes a display panel and a printed circuit board. The display panel includes an active area configured to display an image, a bending area in which a substrate of the display panel is bent, a bonding area in which the printed circuit board is bonded to the display panel, and a crack test area including a test pattern. A plurality of test points disposed on the printed circuit board. The test points, the printed circuit board, the bonding area, the bending area, and the crack test area for a test path.

In an embodiment, the test points may include a first test point, a second test point, a third test point, and a fourth test point.

In an embodiment, a current source may be connected to the first test point and the second test point. A voltmeter may be connected to the third test point and the fourth test point.

In an embodiment, an ammeter may be connected to the first test point and the second test point. A voltage source may be connected to the third test point and the fourth test point.

In an embodiment, the display apparatus may further include a driving chip mounted on the substrate of the display panel. The test path may include the test points, the printed circuit board, the bonding area BO, a portion of the driving chip, the bending area, and the crack test area.

In an embodiment, the test points may include a first test point, a second test point, a third test point and a fourth test point. The test path may include a first resistor connected to the first test point and corresponding to the printed circuit board, a second resistor connected to the first resistor and corresponding to a first adhesive material disposed in the bonding area, a third resistor connected to the second resistor and corresponding to the substrate of the display panel, a fourth resistor connected to the third resistor and corresponding to the driving chip, a fifth resistor connected to the second test point and corresponding to the printed circuit board, a sixth resistor connected to the fifth resistor and corresponding to a second adhesive material disposed in the bonding area, a seventh resistor connected to the sixth resistor and corresponding to the substrate of the display panel, an eighth resistor connected to the seventh resistor and corresponding to the driving chip, a ninth resistor connected to the third test point and corresponding to the printed circuit board, a tenth resistor connected to the ninth resistor and corresponding to a third adhesive material disposed in the bonding area, an eleventh resistor connected to the tenth resistor and corresponding to the substrate of the display panel, a twelfth resistor connected to the eleventh resistor and corresponding to the driving chip, a thirteenth resistor connected to the fourth test point and corresponding to the printed circuit board, a fourteenth resistor connected to the thirteenth resistor and corresponding to a fourth adhesive material disposed in the bonding area, a fifteenth resistor connected to the fourteenth resistor and corresponding to the substrate of the display panel, a sixteenth resistor connected to the fifteenth resistor and corresponding to the driving chip, a first crack test resistor connected between the fourth resistor and the eighth resistor and corresponding to the crack test area, a second crack test resistor connected between the eighth resistor and the twelfth resistor and corresponding to the crack test area, and a third crack test resistor connected between the twelfth resistor and the sixteenth resistor and corresponding to the crack test area.

In an embodiment, the crack test area may include a plurality of first crack test patterns disposed adjacent to a first side of the active area and a second side of the active area crossing the first side of the active area.

In an embodiment, the crack test area may include a plurality of second crack test patterns disposed in the bending area of the display panel.

In an embodiment, the second crack test patterns may include a protruding portion.

In an embodiment, the crack test area may include a plurality of third crack test patterns disposed adjacent to a hole area in the active area of the display panel.

In an embodiment, the plurality of test points is configured to receive a test voltage. When the test voltage is less than a predetermined reference voltage, a crack of the display panel may be detected.

In an embodiment, the plurality of test points is configured to receive a test current. When the test current is outside a range of a first reference current and a second reference current at a test time point in a determining cycle, a crack of the display panel may be detected.

In an embodiment, when a test point of the plurality of test points receives a test signal that does not exceed a reference signal in a determining cycle or exceeds the reference signal two or more times in the determining cycle, a crack of the display panel may be detected.

In an embodiment, a crack of the display panel may be detected using a test circuit. The test circuit may include a reference resistor including a first electrode configured to receive a reference signal and a second electrode connected to a first node and a transistor including a control electrode configured to receive a test signal from a test point of the plurality of test points, a first electrode connected to the first node and a second electrode connected to a ground. A crack of the display panel may be detected based on a signal of the first node.

In an embodiment of the present inventive concept, the display apparatus includes a display panel and a driving chip. The display panel includes an active area configured to display an image, a bending area in which a substrate of the display panel is bent, and a crack test area including a test pattern. The driving chip may be mounted on the substrate. The substrate may include a plurality of test points. The test points, the substrate of the display panel, a portion of the driving chip, the bending area, and the crack test area form a test path.

In an embodiment, the test points may include a first test point, a second test point, a third test point and a fourth test point. The test path may include a first resistor connected to the first test point and corresponding to the substrate of the display panel, a second resistor connected to the first resistor and corresponding to the driving chip, a third resistor connected to the second test point and corresponding to the substrate of the display panel, a fourth resistor connected to the third resistor and corresponding to the driving chip, a fifth resistor connected to the third test point and corresponding to the substrate of the display panel, a sixth resistor connected to the fifth resistor and corresponding to the driving chip, a seventh resistor connected to the fourth test point and corresponding to the substrate of the display panel, an eighth resistor connected to the seventh resistor and corresponding to the driving chip, a first crack test resistor connected between the second resistor and the fourth resistor and corresponding to the crack test area, a second crack test resistor connected between the fourth resistor and the sixth resistor and corresponding to the crack test area, and a third crack test resistor connected between the sixth resistor and the eighth resistor and corresponding to the crack test area.

In an embodiment of the present inventive concept, the electronic apparatus includes a printed circuit board, a display panel, a flexible circuit board, a display panel driver, and a processor. The printed circuit board includes a plurality of test points and a first bonding area bonding a flexible printed circuit. The display panel includes an active area configured to display an image, a second bonding area bonding the display panel and the flexible circuit board, and a crack test area including a test pattern. The flexible circuit board is bonded at the first bonding area. The display panel driver is configured to drive the display panel. The processor is configured to output image data and a control signal to the display panel driver. The test points, the printed circuit board, the first bonding area, the flexible circuit board, the second bonding area, and the crack test area form a test path.

In an embodiment, the test points may include a first test point, a second test point, a third test point and a fourth test point. The test path may include a first resistor connected to the first test point and corresponding to the printed circuit board, a second resistor connected to the first resistor and corresponding to a first adhesive material disposed in the first bonding area, a third resistor connected to the second resistor and corresponding to the flexible circuit board, a fourth resistor connected to the third resistor and corresponding to a second adhesive material disposed in the second bonding area, a fifth resistor connected to the second test point and corresponding to the printed circuit board, a sixth resistor connected to the fifth resistor and corresponding to a third adhesive material disposed in the first bonding area, a seventh resistor connected to the sixth resistor and corresponding to the flexible circuit board, an eighth resistor connected to the seventh resistor and corresponding to a fourth adhesive material disposed in the second bonding area, a ninth resistor connected to the third test point and corresponding to the printed circuit board, a tenth resistor connected to the ninth resistor and corresponding to a fifth adhesive material disposed in the first bonding area, an eleventh resistor connected to the tenth resistor and corresponding to the flexible circuit board, a twelfth resistor connected to the eleventh resistor and corresponding to a sixth adhesive material disposed in the second bonding area, a thirteenth resistor connected to the fourth test point and corresponding to the printed circuit board, a fourteenth resistor connected to the thirteenth resistor and corresponding to a seventh adhesive material disposed in the first bonding area, a fifteenth resistor connected to the fourteenth resistor and corresponding to the flexible circuit board, a sixteenth resistor connected to the fifteenth resistor and corresponding to an eighth adhesive material disposed in the second bonding area, a first crack test resistor connected between the fourth resistor and the eighth resistor and corresponding to the crack test area, a second crack test resistor connected between the eighth resistor and the twelfth resistor and corresponding to the crack test area, and a third crack test resistor connected between the twelfth resistor and the sixteenth resistor and corresponding to the crack test area.

In an embodiment of the present inventive concept, the electronic device includes a display panel, a printed circuit board, a display panel driver and a processor. A printed circuit board including a plurality of test points and a first bonding area bonding a flexible printed circuit, a display panel including an active area configured to display an image, a second bonding area bonding the display panel and the flexible circuit board, and a crack test area including a test pattern The display panel driver drives the display panel. The processor outputs image data and a control signal to the display panel driver. The test points, the printed circuit board, the bonding area, the bending area, and the crack test area form a test path.

In an embodiment, the test points may include a first test point, a second test point, a third test point and a fourth test point. A current source may be connected to the first test point and the second test point and a voltmeter may be connected to the third test point and the fourth test point.

In an embodiment, the test points may include a first test point, a second test point, a third test point and a fourth test point. An ammeter may be connected to the first test point and the second test point and a voltage source may be connected to the third test point and the fourth test point.

According to the display apparatus and the electronic apparatus including the display apparatus, the crack of the display panel may be determined using the test path including the test point, the printed circuit board, the bonding area of the display panel, the bending area of the display panel, and the crack test area of the display panel.

In addition, the crack of the display panel may be determined using the test path including the test point, the driving chip peripheral area of the display panel, the inside of the driving chip, the bending area of the display panel, and the crack test area of the display panel.

The crack of the display panel may be determined using the test path including the test point, the printed circuit board, the first bonding area of the printed circuit board, the flexible circuit board, the second bonding area of the display panel, and the crack test area of the display panel.

As described above, the crack of the display panel may be accurately and efficiently determined using the auto resistance test method.

### BRIEF DESCRIPTION OF THE DRAWINGS

The above and other features of the present inventive concept are apparent from the detailed description with reference to the accompanying drawings, in which:

FIG. 1 is a block diagram illustrating a display apparatus according to an embodiment of the present inventive concept;

FIG. 2 is a diagram illustrating an example of the display apparatus of FIG. 1 including a test path configured to determine a first crack of a display panel;

FIG. 3 is a cross-sectional view illustrating the display apparatus of FIG. 2 including the test path of FIG. 2;

FIG. 4A is an example of a circuit diagram illustrating the test path of FIG. 2;

FIG. 4B is an example of a circuit diagram illustrating the test path of FIG. 2;

FIG. 5 is a diagram illustrating an example of the display apparatus of FIG. 1 including a test path configured to determine a second crack of a display panel;

FIG. 6 is a diagram illustrating an example of the display apparatus of FIG. 1 including a test path configured to determine a third crack of a display panel;

FIG. 7 is a diagram illustrating an example of a display apparatus including a test path configured to determine a first crack of a display panel;

FIG. 8 is a cross-sectional view illustrating the display apparatus of FIG. 7 including the test path of FIG. 7;

FIG. 9A is an example of a circuit diagram illustrating the test path of FIG. 7;

FIG. 9B is an example of a circuit diagram illustrating the test path of FIG. 7;

FIG. 10 is a diagram illustrating an example of a display apparatus including a test path configured to determine a first crack of a display panel;

FIG. 11 is a cross-sectional view illustrating the display apparatus of FIG. 10 including the test path of FIG. 10;

FIG. 12A is an example of a circuit diagram illustrating the test path of FIG. 10;

FIG. 12B is an example of a circuit diagram illustrating the test path of FIG. 10;

FIG. 13A is a graph illustrating a method for determining a crack in a display apparatus according to an embodiment of the present inventive concept;

FIG. 13B is a graph illustrating a method for determining a crack in a display apparatus according to an embodiment of the present inventive concept;

FIG. 13C is a graph illustrating a method for determining a crack in a display apparatus according to an embodiment of the present inventive concept;

FIG. 13D is a graph illustrating a method for determining a crack in a display apparatus according to an embodiment of the present inventive concept;

FIG. 14 is a block diagram illustrating an electronic apparatus according to an embodiment of the present inventive concept;

FIG. 15 is a diagram illustrating an example in which the electronic apparatus of FIG. 14 is implemented as a smartphone; and

FIG. 16 is a block diagram illustrating an electronic apparatus according to an embodiment of the present inventive concept.

### DETAILED DESCRIPTION

Hereinafter, embodiments of the present inventive concept are described in detail with reference to the accompanying drawings. The same reference numerals can l be used for indicating may be used to indicate the same elements disclosure and the drawings. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

The terms "on", "connected", "coupled," etc., used herein refers to a relative placement between elements. For example, a layer, region, or element is referred to as being formed on another layer, region, or element, the layer, region, or element can be directly or indirectly formed on the other layer, region, or element. For example, intervening layers, regions, or elements may be present between the layers, regions, or elements, respectively. As used herein, the term “top surface” may also be referred to as “upper surface”.

The terms such as "first", "second", "below", "under", "above," "on," etc., are used in a relative sense to distinguish different elements or positions, and do not specify an absolute position or an absolute order. These terms are used to distinguish one element from another element. For example, a first element discussed below could be termed a second element without departing from the teachings of the present invention. Similarly, the second element could also be termed the first element.

Embodiments of the present disclosure provide a display apparatus in which a crack of a display panel may be determined using a test path including a plurality of test points disposed on a printed circuit board, a bonding area of the display panel, a bending area of the display panel, and a crack test area including a plurality of test patterns. By passing the test path through these regions, embodiments of the present disclosure enable detection of display panel cracks and bending cracks through an automated resistance test, thereby improving inspection accuracy and reliability.

Embodiments of the present disclosure further provide a display apparatus in which the crack of a display panel may be determined by a test path including a plurality of test points, a peripheral area of a driving chip, an inside region of the driving chip, a bending area of the display panel, and a crack test area. By configuring the test path to traverse the chip peripheral and internal regions in addition to the bending and crack test areas, embodiments of the present disclosure enable detection of cracks caused by stresses at the chip to panel interface or internal defects of the chip.

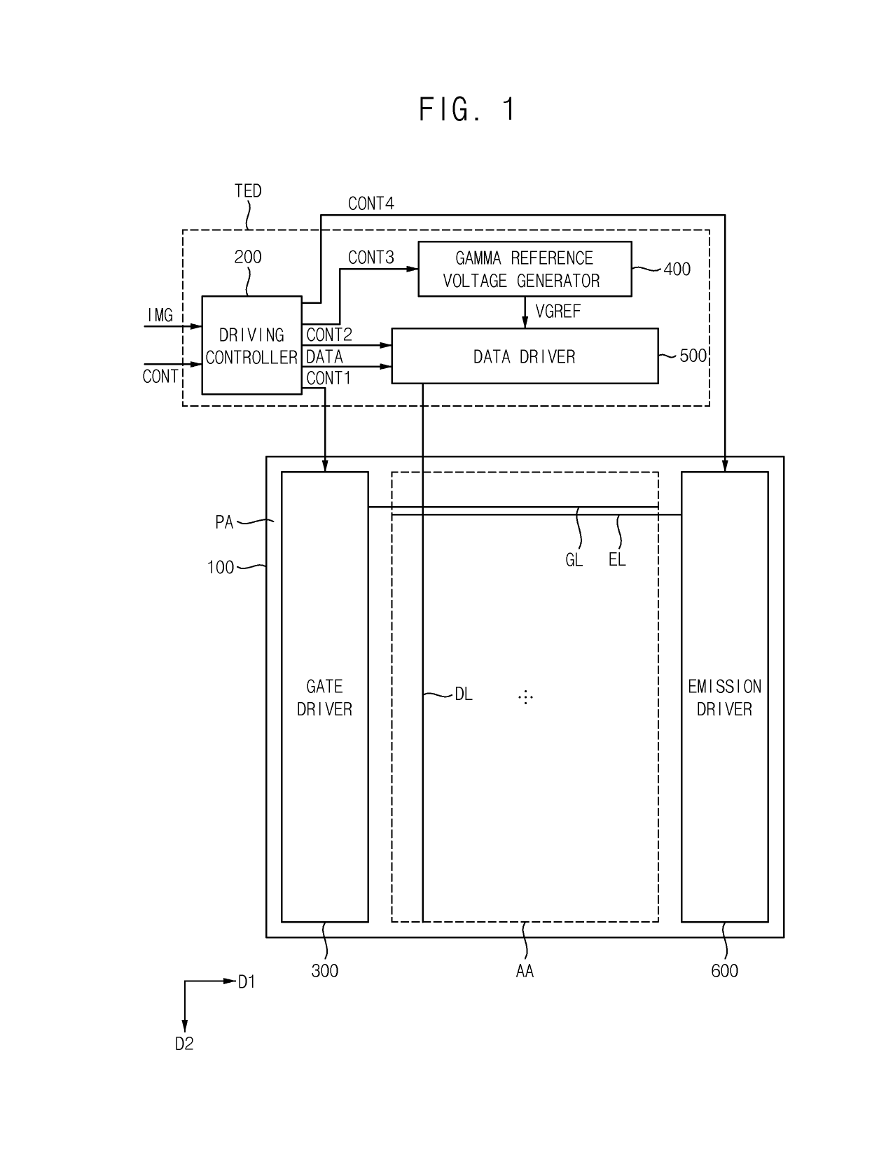

FIG. 1 is a block diagram illustrating a display apparatus according to an embodiment of the present disclosure.

Referring to FIG. 1, the display apparatus includes a display panel 100 and a display panel driver. The display panel driver includes a driving controller 200, a gate driver 300, a gamma reference voltage generator 400, a data driver 500, and an emission driver 600. In some embodiments, the display panel driver may further include additional control circuits or timing controllers electrically connected to the driving controller 200.

The display panel 100 has a display region AA on which an image is displayed and a peripheral region PA adjacent to the display region AA. In some embodiments, the display region AA may correspond to an active area in which pixels are arranged, and the peripheral region PA may correspond to a non-display area accommodating wirings, pads, or driver circuits. In some embodiments, the controllers and drivers disposed in the display panel 100 may be configured to detect one or more cracks within the display panel 100.

The display panel 100 may include a plurality of gate lines GL, a plurality of data lines DL, a plurality of emission lines EL, and a plurality of pixels electrically connected to the gate lines GL, the data lines DL, and the emission lines EL. The gate lines GL may extend in a first direction D1, the data lines DL may extend in a second direction D2 crossing the first direction D1, and the emission lines EL may extend in the first direction D1. In some embodiments, the emission lines EL may extend in a direction different from the gate lines GL based on the pixel arrangement structure. The pixels may be organic light emitting diode (OLED) pixels, liquid crystal display (LCD) pixels, light emitting diode (LED) pixels, or other emissive or non-emissive pixel structures.

The driving controller 200 may receive input image data IMG and an input control signal CONT from an external apparatus (e.g. a processor). For example, the input image data IMG may include red image data, green image data, and blue image data. The input image data IMG may include white image data. The input image data IMG may further include magenta image data, cyan image data, and yellow image data. The input control signal CONT may include a master clock signal and a data enable signal. The input control signal CONT may further include a vertical synchronizing signal and a horizontal synchronizing signal. In some embodiments, the input control signal CONT may include a power control signal for synchronizing with other components of the electronic apparatus

The driving controller 200 generates a first control signal CONT1, a second control signal CONT2, a third control signal CONT3, a fourth control signal CONT4, and a data signal DATA based on the input image data IMG and the input control signal CONT. In some embodiments, the driving controller 200 may generate additional control signals for error detection, compensation, or calibration of the display panel 100.

The driving controller 200 generates the first control signal CONT1 for controlling an operation of the gate driver 300 based on the input control signal CONT, and outputs the first control signal CONT1 to the gate driver 300. The first control signal CONT1 may include a vertical start signal and a gate clock signal. In some embodiments, the first control signal CONT1 may include a gate enable signal or a gate reset signal to control the operation of the gate driver 300.

The driving controller 200 generates the second control signal CONT2 for controlling an operation of the data driver 500 based on the input control signal CONT, and outputs the second control signal CONT2 to the data driver 500. The second control signal CONT2 may include a horizontal start signal and a load signal.

The driving controller 200 generates the data signal DATA based on the input image data IMG. The driving controller 200 outputs the data signal DATA to the data driver 500 for conversion into data voltages corresponding to pixel values.

The driving controller 200 generates the third control signal CONT3 for controlling an operation of the gamma reference voltage generator 400 based on the input control signal CONT, and outputs the third control signal CONT3 to the gamma reference voltage generator 400. In some embodiments, the third control signal CONT3 may include a gamma update enable signal, a reference voltage selection signal, or a calibration signal for adjusting gray scale levels.

The driving controller 200 generates the fourth control signal CONT4 for controlling an operation of the emission driver 600 based on the input control signal CONT, and outputs the fourth control signal CONT4 to the emission driver 600.

The gate driver 300 generates gate signals for driving the gate lines GL in response to the first control signal CONT1 received from the driving controller 200. The gate driver 300 may output the gate signals to the gate lines GL. For example, the gate driver 300 may be integrated on the peripheral region PA of the display panel 100. For example, the gate driver 300 may be mounted on the peripheral region PA of the display panel 100. In some cases, the gate driver 300 may be implemented as a separate integrated circuit mounted on the peripheral region PA of the display panel 100 or on a printed circuit board PCB electrically connected to the display panel 100.

The gamma reference voltage generator 400 generates a gamma reference voltage VGREF in response to the third control signal CONT3 received from the driving controller 200. The gamma reference voltage generator 400 provides the gamma reference voltage VGREF to the data driver 500. The gamma reference voltage VGREF is used for converting the data signal DATA into analog-type data voltage.

In an embodiment, the gamma reference voltage generator 400 may be disposed within the driving controller 200, within the data driver 500, or implemented as a separate integrated circuit electrically connected thereto.

The data driver 500 receives the second control signal CONT2 and the data signal DATA from the driving controller 200, and receives the gamma reference voltages VGREF from the gamma reference voltage generator 400. The data driver 500 converts the data signals DATA into analog-type data voltages using the gamma reference voltages VGREF. The data driver 500 outputs the data voltages to the data lines DL.

In an embodiment, the driving controller 200 and the data driver 500 may be integrally formed. In an embodiment, the driving controller 200, the gamma reference voltage generator 400 and the data driver 500 may be integrally formed. A driving unit including at least the driving controller 200 and the data driver 500 may be referred to as a timing controller embedded data driver (TED). In some embodiments, the timing controller embedded data driver TED may further include additional circuits such as a power supply unit, a calibration circuit, or other circuits or units.

The emission driver 600 generates emission signals for driving the emission lines EL in response to the fourth control signal CONT4 received from the driving controller 200. The emission driver 600 may output the emission signals to the emission lines EL. For example, the emission driver 600 may be integrated on the peripheral region PA of the display panel 100. For example, the emission driver 600 may be mounted on the peripheral region PA of the display panel 100. In some cases, the emission driver 600 may be implemented as a separate integrated circuit mounted on the peripheral region PA of the display panel 100 or disposed on a printed circuit board PCB electrically connected to the display panel 100.

Although the gate driver 300 is disposed at a first side of the display panel 100 and the emission driver 600 is disposed at a second side of the display panel 100 opposite to the first side in FIG. 1, the present inventive concept is not necessarily limited thereto. For example, both of the gate driver 300 and the emission driver 600 may be disposed at the first side of the display panel 100. For example, the gate driver 300 and the emission driver 600 may be integrally formed as a single driver circuit. In some embodiments, the gate driver 300 and the emission driver 600 may be disposed on adjacent sides of the display panel 100, or may be mounted together on a printed circuit board PCB electrically connected to the display panel 100.

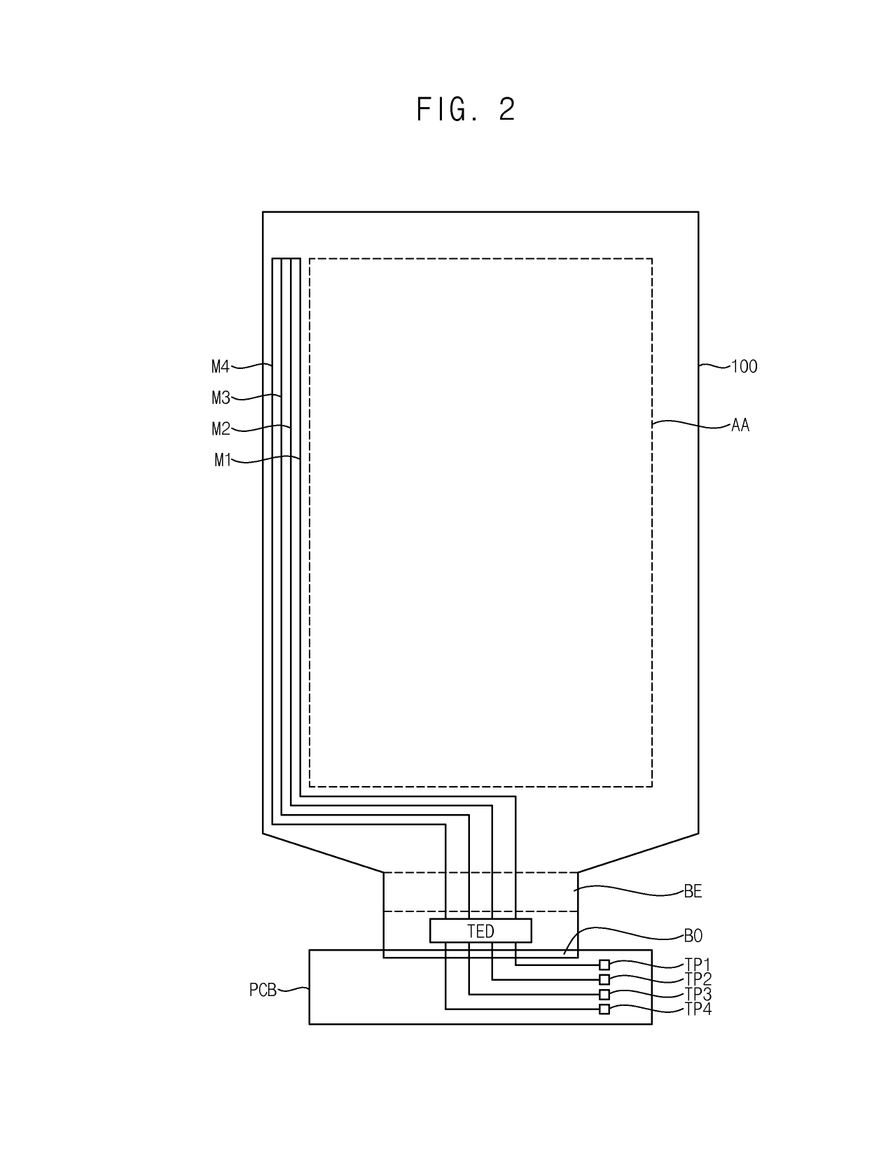

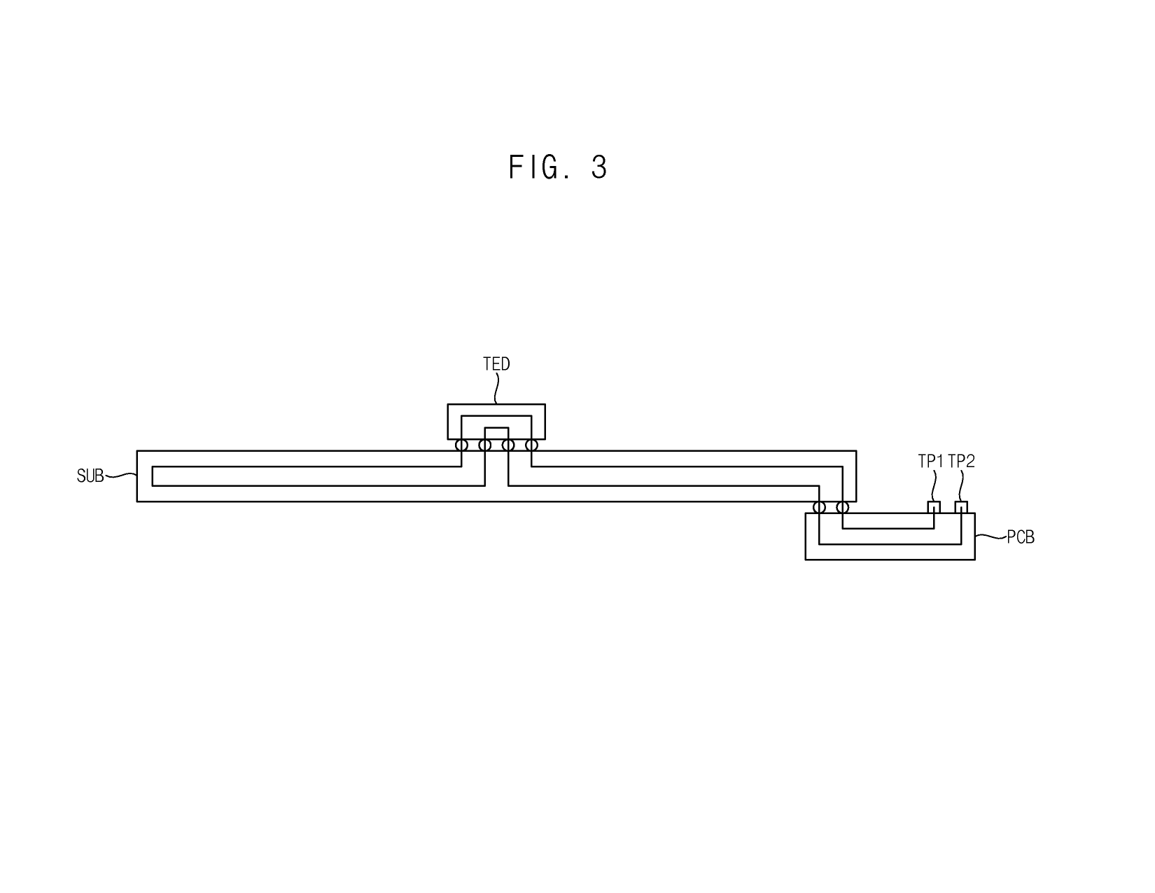

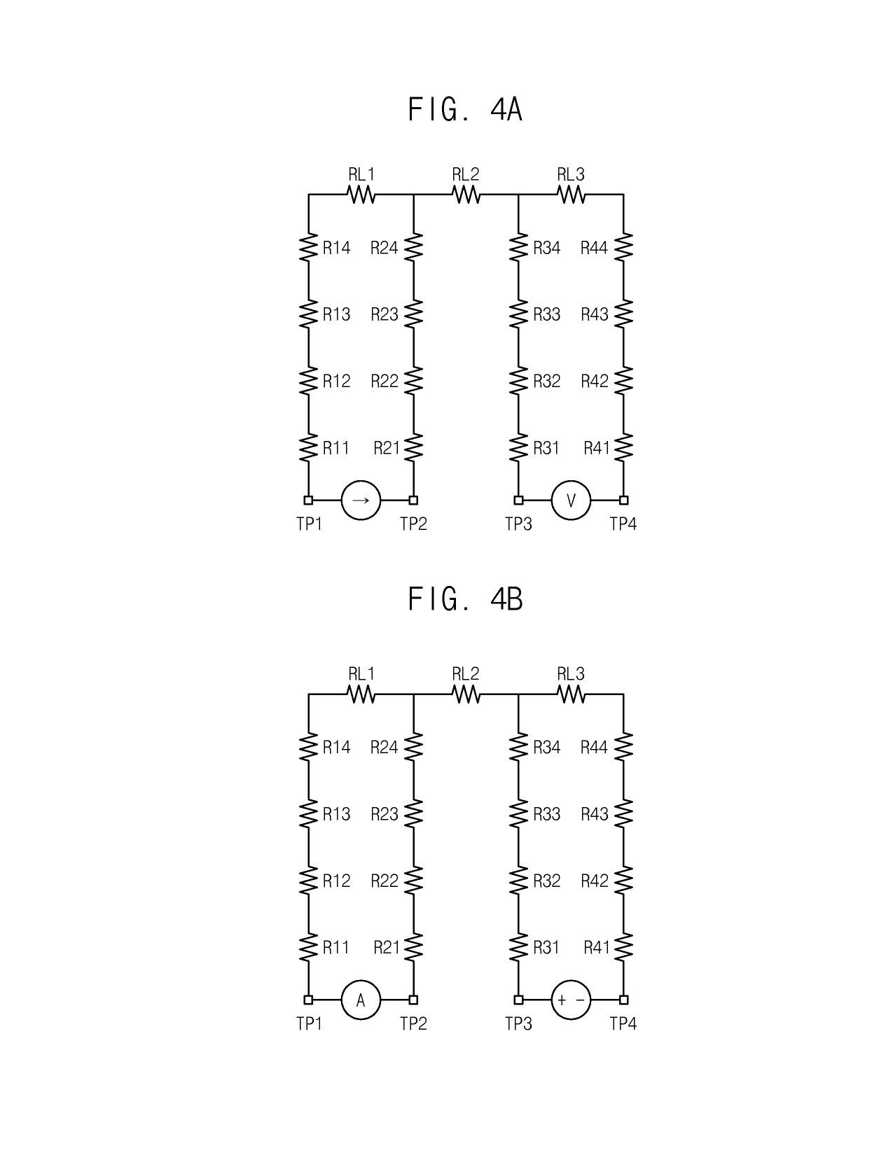

FIG. 2 is a diagram illustrating an example of the display apparatus of FIG. 1 including a test path configured to determine a first crack of the display panel 100. FIG. 3 is a cross-sectional view illustrating the display apparatus of FIG. 2 including the test path of FIG. 2. FIG. 4A is an example of a circuit diagram illustrating the test path of FIG. 2. FIG. 4B is an example of a circuit diagram illustrating the test path of FIG. 2.

Referring to FIGS. 1 to 4B, the display apparatus includes the display panel 100 and a printed circuit board PCB. The display panel 100 includes an active area (also referred to as the display region) AA on which an image is displayed, a bending area BE in which a substrate SUB is bent, a bonding area BO in which the printed circuit board PCB is bonded, and a crack test area in which test patterns M1, M2, M3, and M4 for a crack test are disposed. The printed circuit board PCB is bonded to the bonding area BO of the display panel 100. The printed circuit board PCB includes a plurality of test points TP1, TP2, TP3, and TP4. In some embodiments, the crack test area may be disposed along an edge of the display panel 100 to detect a crack.

The test path sequentially includes the test points TP1, TP2, TP3, and TP4, the printed circuit board PCB, the bonding area BO, the bending area BE, and the crack test area. In some embodiments, the test path may further include additional intermediate conductive traces or connectors disposed on the PCB to facilitate electrical connection between the test points TP1–TP4 and the crack test patterns M1, M2, M3, and M4. For example, the test path sequentially includes the test points TP1, TP2, TP3, and TP4, the printed circuit board PCB, the bonding area BO, the bending area BE, and the crack test area.

As shown in FIG. 3, the test path extends through a multilayer structure including the printed circuit board PCB, a first adhesive layer disposed in the bonding area BO, the substrate SUB of the display panel 100, a second adhesive layer, and the driving chip TED sequentially arranged. Each layer may correspond to a resistance portion in the test path. In some cases, when a crack occurs in one of these layers, the resistance of the test path may increase and may be detected by monitoring a change in the test signal.

The plurality of test points may include a first test point TP1, a second test point TP2, a third test point TP3, and a fourth test point TP4. In some embodiments, additional test points may be provided to increase crack detection resolution or to enable detection across multiple regions of the display panel 100. However, embodiments of the present disclosure are not necessarily limited thereto. For example, the display panel 100 may include one or more text points.

As shown in FIG. 4A, a current source may be connected to the first test point TP1 and the second test point TP2. A voltmeter may be connected to the third test point TP3 and the fourth test point TP4. For example, a test signal may correspond to a test voltage measured by the voltmeter. In some cases, the voltage may vary in response to changes in resistance along the test path caused by cracks in the display panel 100

In an embodiment, as shown in FIG. 4B, an ammeter may be connected to the first test point TP1 and the second test point TP2. A voltage source may be connected to the third test point TP3 and the fourth test point TP4. For example, the test signal may correspond to a test current measured by the ammeter, where the current varies in response to resistance changes introduced by cracks in the test path of the display panel 100.

The display apparatus may further include a driving chip mounted on the substrate SUB of the display panel 100. The driving chip may be the timing controller embedded data driver TED. In some embodiments, the driving chip may further include a power supply unit (or circuit), a compensation circuit, or a crack detection circuit electrically connected to the test path.

For example, the test path may sequentially include the test points TP1, TP2, TP3, and TP4, the printed circuit board PCB, the bonding area BO, a region of the driving chip TED, the bending area BE, and the crack test area. In some embodiments, additional intermediate wirings may be disposed within the TED to form as a part of the test path to enhance sensitivity in detecting cracks.

As shown in FIGS. 3, 4A, and 4B, the test path may include a first resistor R11 connected to the first test point TP1 and corresponding to the printed circuit board PCB, a second resistor R12 connected to the first resistor R11 and corresponding to a first adhesive material disposed in the bonding area BO, a third resistor R13 connected to the second resistor R12 and corresponding to the substrate SUB of the display panel 100, and a fourth resistor R14 connected to the third resistor R13 and corresponding to the driving chip TED. The test path may further include a fifth resistor R21 connected to the second test point TP2 and corresponding to the printed circuit board PCB, a sixth resistor R22 connected to the fifth resistor R21 and corresponding to a second adhesive material disposed in the bonding area BO, a seventh resistor R23 connected to the sixth resistor R22 and corresponding to the substrate SUB of the display panel 100, an eighth resistor R24 connected to the seventh resistor R23 and corresponding to the driving chip TED. The test path may further include a ninth resistor R31 connected to the third test point TP3 and corresponding to the printed circuit board PCB, a tenth resistor R32 connected to the ninth resistor R31 and corresponding to a third adhesive material disposed in the bonding area BO, an eleventh resistor R33 connected to the tenth resistor R32 and corresponding to the substrate SUB of the display panel 100, a twelfth resistor R34 connected to the eleventh resistor R33 and corresponding to the driving chip TED. The test path may further include a thirteenth resistor R41 connected to the fourth test point TP4 and corresponding to the printed circuit board PCB, a fourteenth resistor R42 connected to the thirteenth resistor R41 and corresponding to a fourth adhesive material disposed in the bonding area BO, a fifteenth resistor R43 connected to the fourteenth resistor R42 and corresponding to the substrate SUB of the display panel 100, a sixteenth resistor R44 connected to the fifteenth resistor R43 and corresponding to the driving chip TED. In one aspect, the test path may further include a first crack test resistor RL1 connected between the fourth resistor R14 and the eighth resistor R24 and corresponding to the crack test area, a second crack test resistor RL2 connected between the eighth resistor R24 and the twelfth resistor R34 and corresponding to the crack test area, and a third crack test resistor RL3 connected between the twelfth resistor R34 and the sixteenth resistor R44 and corresponding to the crack test area. In some embodiments, additional crack test resistors may be arranged in parallel or series to improve detection resolution or redundancy.

Each resistor element R11–R44 corresponds to a structural portion of the test path and is connected to a corresponding test point TP1-TP4, and each crack test resistor RL1–RL3 corresponds to a connecting portion between adjacent test patterns M1–M4. A crack occurring in the PCB, adhesive, substrate SUB, or TED increases the resistance of the corresponding resistor element, and a crack in the crack test area increases the resistance of RL1, RL2, or RL3. Accordingly, by measuring the overall resistance of the test path and comparing the measured resistance to a predetermined (or target) reference resistance, cracks in different physical regions of the display apparatus can be detected and localized.

For example, the first crack test resistor RL1 may correspond to a first test pattern M1 of FIG. 2, a second test pattern M2 of FIG. 2, and a connecting portion between the first test pattern M1 and the second test pattern M2. In some embodiments, the connecting portion may be formed of a conductive trace or line disposed in the crack test area.

For example, the second crack test resistor RL2 may correspond to the second test pattern M2 of FIG. 2, a third test pattern M3 of FIG. 2, and a connecting portion between the second test pattern M2 and the third test pattern M3.

For example, the third crack test resistor RL3 may correspond to the third test pattern M3 of FIG. 2, a fourth test pattern M4 of FIG. 2, and a connecting portion between the third test pattern M3 and the fourth test pattern M4.

For example, two test points TP1 and TP2 are illustrated in a cross-sectional view of FIG. 3 and positions of the test points TP1 and TP2 of FIG. 3 may be different from positions of the test points TP1 and TP2 of FIG. 2. In addition, positions and number of adhesive materials between the printed circuit board PCB and the substrate SUB of the display panel 100, and positions and number of adhesive materials between the substrate SUB of the display panel 100 and the driving chip TED may be simplified in FIG. 3.

For example, the fourth resistor R14, the eighth resistor R24, the twelfth resistor R34, the sixteenth resistor R44 corresponding to the driving chip TED may correspond to a resistance of the adhesive material in a portion where the test path enters the driver chip TED, a resistance of the adhesive material in a portion where the test path exits the driver chip TED, and a wiring resistance inside the driver chip TED. In some embodiments, the wiring resistance may vary based on layout or metal line thickness.

Although all test paths are illustrated as passing through the inside of the driving chip TED in FIG. 3, the present inventive concept is not necessarily limited thereto. In an embodiment, some test paths may pass through the inside of the driving chip TED. In some embodiments, test paths may bypass the TED entirely and instead extend directly between the bonding area BO and the crack test area.

In an embodiment, the crack test area may include a plurality of first crack test patterns M1, M2, M3, and M4 disposed adjacent to a first side of the active area AA (e.g. a lower side of the active area AA) and a second side of the active area AA (e.g. a left side of the active area AA) crossing (or perpendicular to) the first side of the active area. In some embodiments, the crack test patterns may be disposed on three or four sides of the active area AA.

The first crack test patterns M1, M2, M3, and M4 may be patterns for detecting a crack in the peripheral region PA of the display panel 100. The first crack test patterns M1, M2, M3, and M4 may be referred to as module crack detection patterns. In some embodiments, the module crack detection patterns may include lines, mesh structures, or electrodes to enhance the detection of cracks.

Although the first crack test patterns M1, M2, M3, and M4 are disposed adjacent to the first side and the second side of the active area AA in the embodiment, the present inventive concept is not necessarily limited thereto.

For example, when the active area AA has a rectangular shape, the first crack test patterns M1, M2, M3, and M4 may be disposed adjacent to three sides or all sides of the active area AA. In some embodiments, the first crack test patterns may be extended diagonally across corner regions of the display panel 100 to further improve crack detection sensitivity. In some embodiments, the active area AA may have a polygonal shape, and the first crack test patterns may be disposed in one or more sides of the active area AA.

According to an embodiment, the crack of the display panel 100 may be determined using the test path including the test point TP1, TP2, TP3, and TP4, the printed circuit board PCB, the bonding area BO of the display panel 100, the bending area BE of the display panel 100, and the crack test area (including M1, M2, M3, and M4) of the display panel 100 sequentially arranged.

As described above, the crack of the display panel 100 may be accurately and efficiently determined using the auto resistance test method (or (auto resistance test method). In some cases, the auto resistance test method may be performed during manufacturing, during quality inspection, or periodically during operation of the display apparatus to enable crack detection and prevention of the electronic device failure.

Accordingly, embodiments of the present disclosure provide a display apparatus that enables automated crack detection using an integrated test path and crack test patterns. The described apparatus uses one or more electrical resistance measurement, which allows accurate, rapid, and repeatable detection of cracks. The auto resistance test method may be executed during manufacturing, during module assembly, or periodically during field operation, thereby improving product reliability and crack detection.

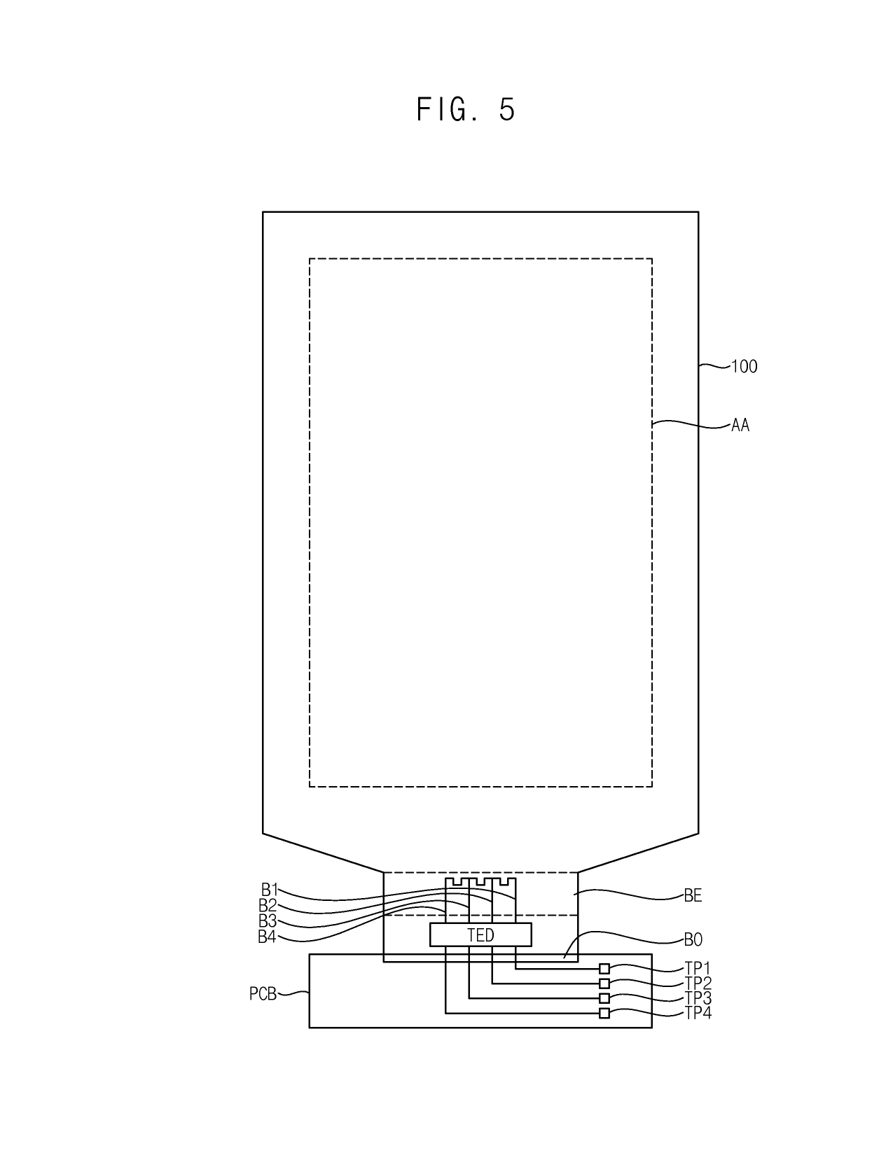

FIG. 5 is a diagram illustrating an example of the display apparatus of FIG. 1 including a test path configured to determine a second crack of a display panel 100.

The display apparatus is substantially the same as the display apparatus of the previous embodiment illustrated in FIGS. 1 to 4B except that a second crack (or a bending crack) of the display panel 100 is determined instead of a first crack (or a module crack) of the display panel 100. Thus, the same reference numerals are used to refer to the same or like parts as those described in the previous embodiment of FIGS. 1 to 4B and differences may be further described.

Referring to FIGS. 1 and 3 to 5, the display apparatus includes the display panel 100 and a printed circuit board PCB. The display panel 100 includes an active area (also referred to as the display region) AA on which an image is displayed, a bending area BE in which a substrate SUB is bent, a bonding area BO in which the printed circuit board PCB is bonded, and a crack test area in which test patterns B1, B2, B3, and B4 for a crack test are disposed. The printed circuit board PCB is bonded to the bonding area BO of the display panel 100. The printed circuit board PCB includes a plurality of test points TP1, TP2, TP3, and TP4. In some cases, the test patterns B1, B2, B3, and B4 are disposed in the bending area BE to electrically sense cracks generated by mechanical stress or repeated bending of the substrate SUB.

The test path sequentially includes the test points TP1, TP2, TP3, and TP4, the printed circuit board PCB, the bonding area BO, the bending area BE, and the crack test area. For example, the test path includes the test points TP1, TP2, TP3, and TP4, the printed circuit board PCB, the bonding area BO, the bending area BE, and the crack test area sequentially arranged. In some embodiments, the test path further extends through the TED mounted on the bonding area BO before entering the bending area BE.

For example, the first crack test resistor RL1 may correspond to a first test pattern B1 of FIG. 5, a second test pattern B2 of FIG. 5, and a connecting portion between the first test pattern B1 and the second test pattern B2.

For example, the second crack test resistor RL2 may correspond to the second test pattern B2 of FIG. 5, a third test pattern B3 of FIG. 5, and a connecting portion between the second test pattern B2 and the third test pattern B3.

For example, the third crack test resistor RL3 may correspond to the third test pattern B3 of FIG. 5, a fourth test pattern B4 of FIG. 5, and a connecting portion between the third test pattern B3 and the fourth test pattern B4. In some embodiments, additional crack test resistors may be disposed between adjacent test patterns to increase resolution of crack detection along the bending area BE. In some cases, when the substrate SUB is bent or repeatedly flexed, cracks may form in the bending area BE. These cracks increase the resistance of the corresponding crack test resistors RL1–RL3 formed between adjacent test patterns B1–B4. The difference of the measured resistance from a predetermined reference value may indicate the presence of the bending crack.

In an embodiment, the crack test area may include a plurality of second crack test patterns B1, B2, B3, and B4 disposed in the bending area BE of the display panel 100.

The second crack test patterns B1, B2, B3, and B4 may be patterns for detecting a crack of the bending area BE of the display panel 100. The second crack test patterns B1, B2, B3, and B4 may be referred to as bending crack detection patterns.

For example, the second crack test patterns may include a protruding portion configured to effectively detect the crack formation within the bending area BE. The protruding portion locally increases mechanical stress concentration, and increases sensitivity to cracks that may be undetectable without the protruding portion.

According to an embodiment, the crack of the display panel 100 may be determined using the test path sequentially including the test point TP1, TP2, TP3, and TP4, the printed circuit board PCB, the bonding area BO of the display panel 100, the bending area BE of the display panel 100, and the crack test area (including B1, B2, B3, and B4) of the display panel 100.

As described above, the crack of the display panel 100 may be accurately and efficiently determined using the auto resistance test method. For example, the integration of the bending crack detection patterns B1–B4 into the test path allows electrical detection of cracks that arise due to repeated flexing or folding of the substrate SUB, which is essential in foldable or flexible display applications.

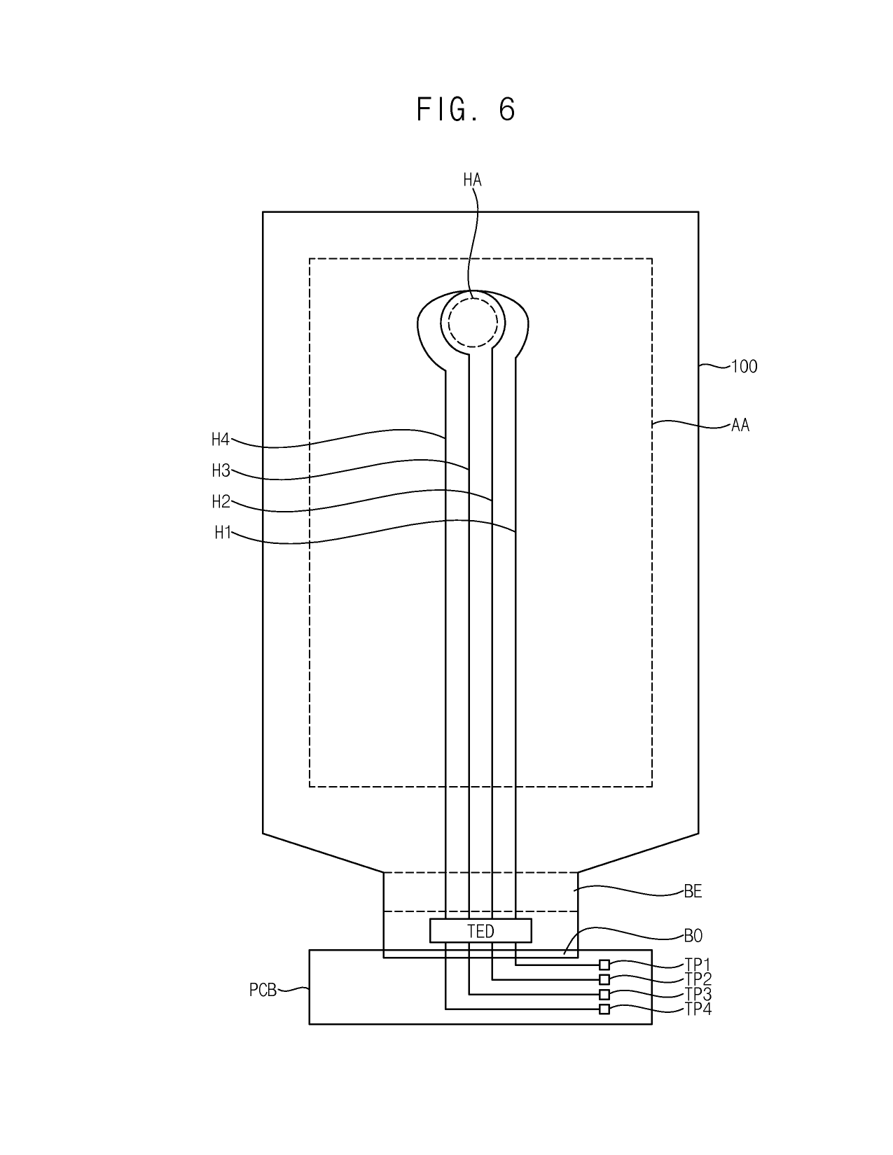

FIG. 6 is a diagram illustrating an example of the display apparatus of FIG. 1 including a test path configured to determine a third crack of a display panel.

The display apparatus is substantially the same as the display apparatus of the embodiment illustrated in FIGS. 1 to 4B except that a third crack (a hole crack) of the display panel 100 is determined instead of the first crack (a module crack) of the display panel 100. Thus, the same reference numerals are used to refer to the same or like parts as those described in the previous embodiment of FIGS. 1 to 4B and differences may be further described.

Referring to FIGS. 1, 3 to 4B, and 6, the display apparatus includes the display panel 100 and a printed circuit board PCB. The display panel 100 includes an active area (also referred to as the display region) AA on which an image is displayed, a bending area BE in which a substrate SUB is bent, a bonding area BO in which the printed circuit board PCB is bonded, and a crack test area in which test patterns H1, H2, H3, and H4 for a crack test are disposed. The printed circuit board PCB is bonded to the bonding area BO of the display panel 100. The printed circuit board PCB includes a plurality of test points TP1, TP2, TP3, and TP4. In some cases, a hole region HA is disposed in the active area AA, and the test patterns H1, H2, H3, and H4 are electrically connected to extend along the hole region HA to detect formation of cracks initiated from the hole.

The test path sequentially includes the test points TP1, TP2, TP3, and TP4, the printed circuit board PCB, the bonding area BO, the bending area BE, and the crack test area. In some cases, the crack test area includes the test patterns H1, H2, H3, and H4 disposed around the hole region HA to detect crack formation.

For example, the first crack test resistor RL1 may correspond to a first test pattern H1 of FIG. 6, a second test pattern H2 of FIG. 6, and a connecting portion between the first test pattern H1 and the second test pattern H2.

For example, the second crack test resistor RL2 may correspond to the second test pattern H2 of FIG. 6, a third test pattern H3 of FIG. 6, and a connecting portion between the second test pattern H2 and the third test pattern H3.

For example, the third crack test resistor RL3 may correspond to the third test pattern H3 of FIG. 6, a fourth test pattern H4 of FIG. 6, and a connecting portion between the third test pattern H3 and the fourth test pattern H4.

In an embodiment, the crack test area may include a plurality of third crack test patterns H1, H2, H3, and H4 disposed adjacent to a hole area HA in the active area AA of the display panel 100.

The third crack test patterns H1, H2, H3, and H4 may be patterns for detecting a crack originating from the hole area HA of the display panel 100. The third crack test patterns H1, H2, H3, and H4 may be referred to as hole crack detection patterns.

For example, the hole area HA may be a camera area or a sensor area defined in the active area AA of the display panel 100. In some cases, since the edge of the hole area HA concentrates mechanical stress, cracks may initiate at the boundary of the hole area and extend radially into the surrounding active area AA towards the peripheral area.

According to an embodiment, the crack of the display panel 100 may be determined using the test path including the test point TP1, TP2, TP3, and TP4, the printed circuit board PCB, the bonding area BO of the display panel 100, the bending area BE of the display panel 100, and the crack test area (including H1, H2, H3, and H4) of the display panel 100 sequentially arranged. In some cases, the test resistors RL1, RL2, and RL3, corresponding to the test patterns H1, H2, H3, and H4, change resistance when cracks form in or near the hole area HA, thus provide an electrical signal of hole cracks.

As described above, the crack of the display panel 100 may be accurately and efficiently determined using the auto resistance test method.

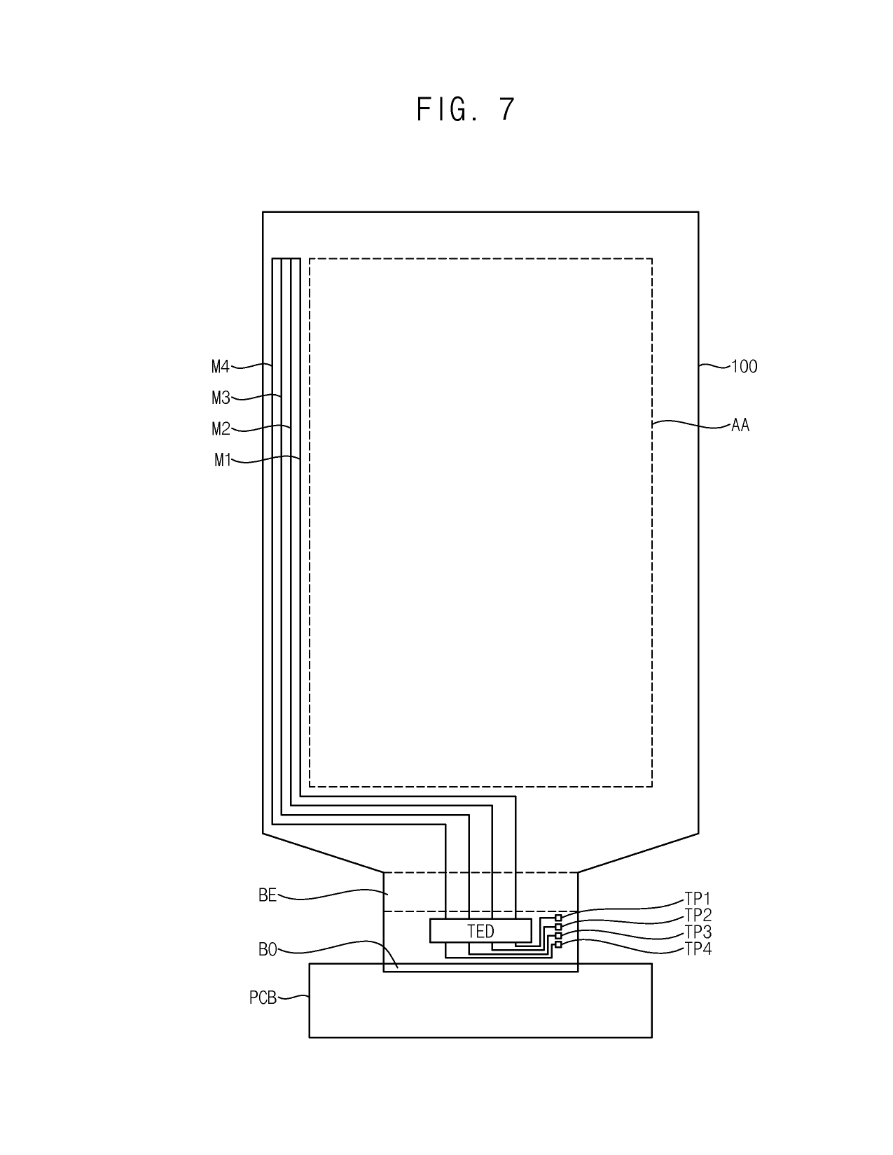

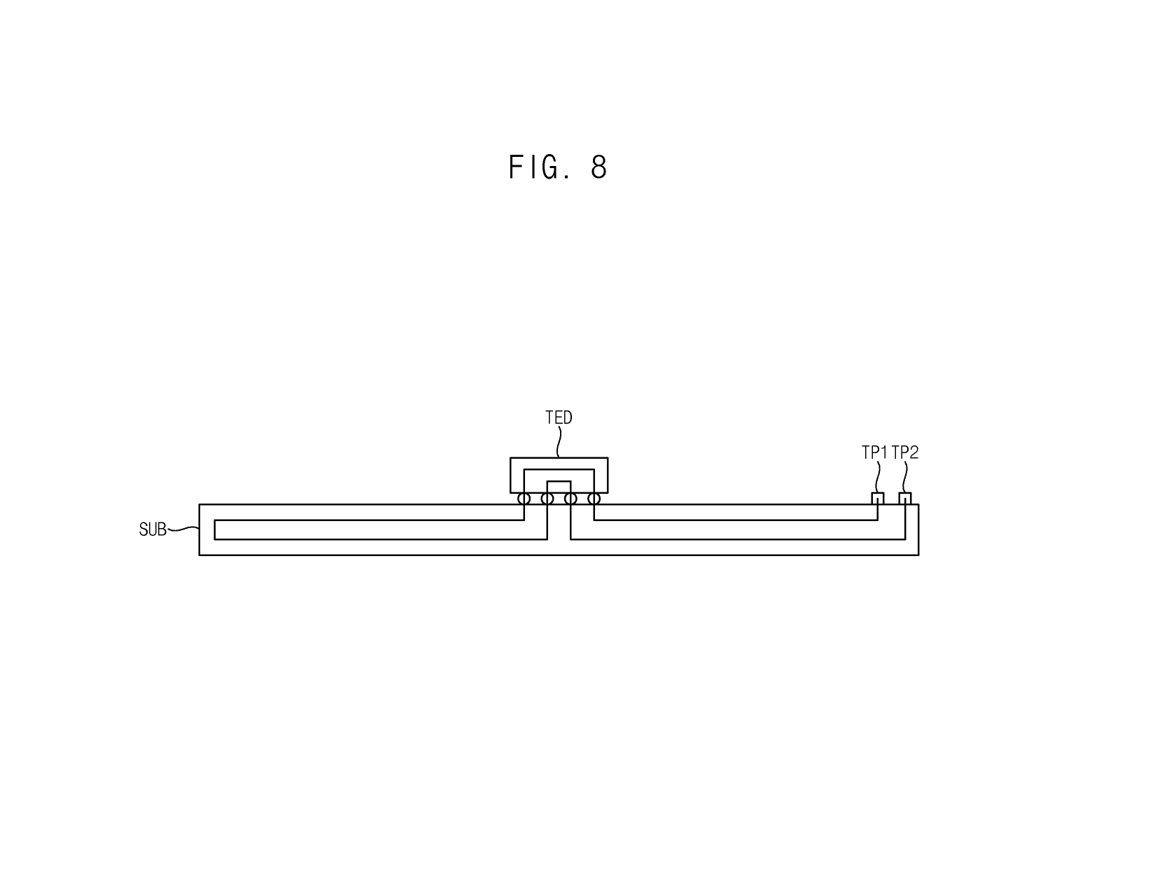

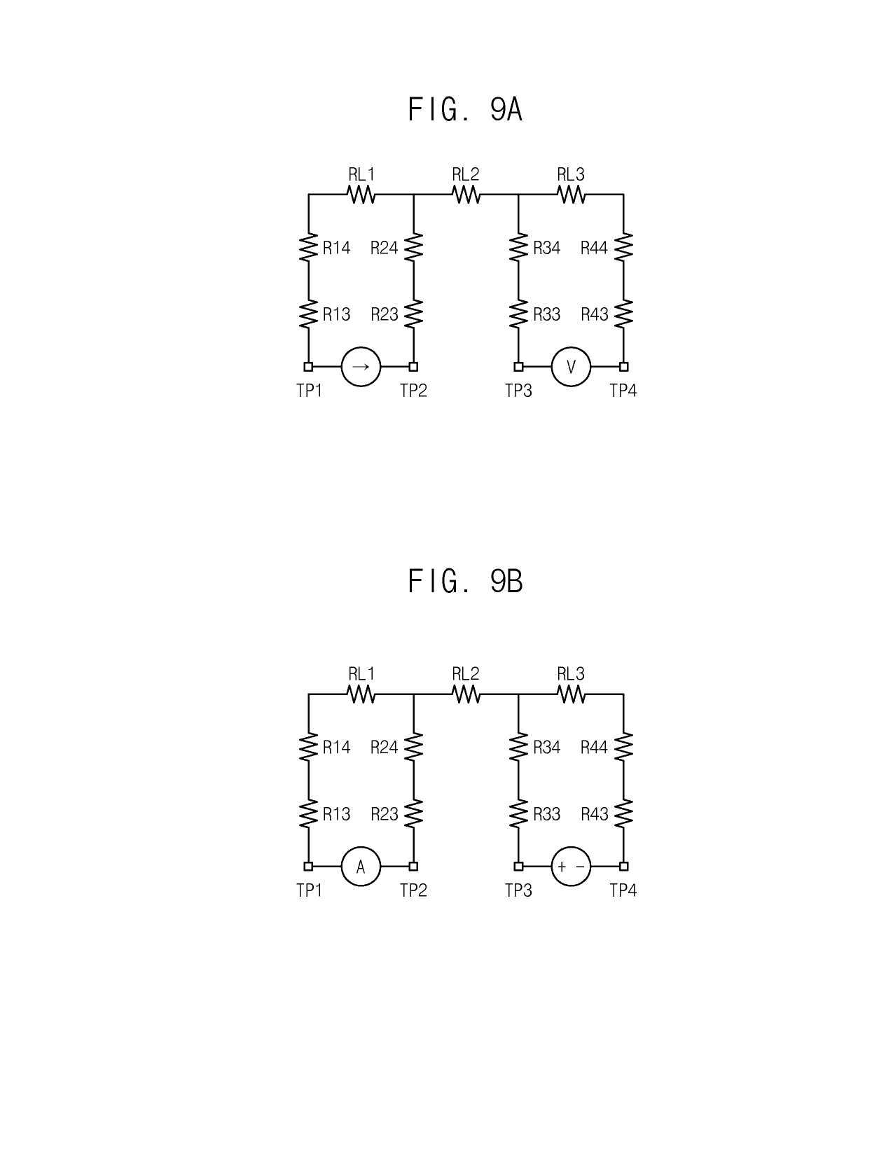

FIG. 7 is a diagram illustrating an example of a display apparatus including a test path configured to determine a first crack of a display panel 100. FIG. 8 is a cross-sectional view illustrating the display apparatus of FIG. 7 including the test path of FIG. 7. FIG. 9A is an example of a circuit diagram illustrating the test path of FIG. 7. FIG. 9B is an example of a circuit diagram illustrating the test path of FIG. 7.

The display apparatus is substantially the same as the display apparatus of the previous embodiment illustrated in FIGS. 1 to 4B except for the test points being disposed on the substrate SUB of the display panel 100 and the test path according to the positions of the test points. Thus, the same reference numerals will be used to refer to the same or like parts as those described in the previous embodiment of FIGS. 1 to 4B and differences may be further described.

Referring to FIGS. 1 and 7 to 9B, the display apparatus includes the display panel 100 and a driving chip TED. The display panel 100 includes an active area (also referred to as the display region) AA on which an image is displayed, a bending area BE in which a substrate SUB is bent, and a crack test area in which test patterns M1, M2, M3, and M4 for a crack test are disposed. The driving chip TED is mounted on the substrate SUB. The substrate SUB of the display panel 100 includes a plurality of test points TP1, TP2, TP3, and TP4. In some cases, the test points are electrically connected to the test patterns such that the resistance between the test points enable detection of cracks formed in the bending area or the crack test area. The bonding area (BO), shown in FIG. 7, electrically connects the substrate SUB to the printed circuit board PCB and provides an interface between the driving chip TED and external circuits.

In an embodiment, the driving chip may be the timing controller embedded data driver TED.

The test path includes the test points TP1, TP2, TP3, and TP4, the substrate SUB of the display panel 100, a driving chip area of the driving chip TED, the bending area BE, and the crack test area. By passing through the bending area and the crack test area, the test path enables localized detection of cracks that may occur within the display panel 100. In some cases,

The plurality of test points may include a first test point TP1, a second test point TP2, a third test point TP3, and a fourth test point TP4. However, embodiments are not necessarily limited thereto. For example, the plurality of test points may include one or more test points.

As shown in FIG. 9A, a current source may be connected to the first test point TP1 and the second test point TP2. A voltmeter may be connected to the third test point TP3 and the fourth test point TP4. For example, a test signal may be a test voltage measured by the voltmeter.

In an embodiment, as shown in FIG. 9B, an ammeter may be connected to the first test point TP1 and the second test point TP2. A voltage source may be connected to the third test point TP3 and the fourth test point TP4. For example, the test signal may be a test current measured by the ammeter.

As shown in FIGS. 8, 9A and 9B, the test path may include a third resistor R13 (or a first resistor) connected to the first test point TP1 and corresponding to the substrate SUB of the display panel 100, a fourth resistor R14 (or a second resistor) connected to the third resistor R13 and corresponding to the driving chip TED, a seventh resistor R23 (or a third resistor) connected to the second test point TP2 and corresponding to the substrate SUB of the display panel 100, an eighth resistor R24 (or a fourth resistor) connected to the seventh resistor R23 and corresponding to the driving chip TED, an eleventh resistor R33 (or a fifth resistor) connected to the third test point TP3 and corresponding to the substrate SUB of the display panel 100, a twelfth resistor R34 (or a sixth resistor) connected to the eleventh resistor R33 and corresponding to the driving chip TED, a fifteenth resistor R43 (or a seventh resistor) connected to the fourth test point TP4 and corresponding to the substrate SUB of the display panel 100, a sixteenth resistor R44 (or an eighth resistor) connected to the fifteenth resistor R43 and corresponding to the driving chip TED. In some cases, the test path may include a first crack test resistor RL1 connected between the fourth resistor R14 and the eighth resistor R24 and corresponding to the crack test area, a second crack test resistor RL2 connected between the eighth resistor R24 and the twelfth resistor R34 and corresponding to the crack test area, and a third crack test resistor RL3 connected between the twelfth resistor R34 and the sixteenth resistor R44 and corresponding to the crack test area. In one aspect, the resistor network may extend through the substrate SUB and the crack test area.

As shown in FIG. 7, the first crack test resistor RL1 may correspond to a first test pattern M1 of FIG. 7, a second test pattern M2 of FIG. 7, and a connecting portion between the first test pattern M1 and the second test pattern M2. The second crack test resistor RL2 may correspond to the second test pattern M2 of FIG. 7, a third test pattern M3 of FIG. 7, and a connecting portion between the second test pattern M2 and the third test pattern M3. The third crack test resistor RL3 may correspond to the third test pattern M3 of FIG. 7, a fourth test pattern M4 of FIG. 7, and a connecting portion between the third test pattern M3 and the fourth test pattern M4. The display apparatus may be configured to detect the module crack of the display panel 100.

In an embodiment, similar to the embodiment illustrated in FIG. 5, the first crack test resistor RL1 may correspond to a first test pattern B1 of FIG. 5, a second test pattern B2 of FIG. 5, and a connecting portion between the first test pattern B1 and the second test pattern B2. The second crack test resistor RL2 may correspond to the second test pattern B2 of FIG. 5, a third test pattern B3 of FIG. 5, and a connecting portion between the second test pattern B2 and the third test pattern B3. The third crack test resistor RL3 may correspond to the third test pattern B3 of FIG. 5, a fourth test pattern B4 of FIG. 5, and a connecting portion between the third test pattern B3 and the fourth test pattern B4. The display apparatus may be configured to detect the bending crack of the display panel 100.

In an embodiment, similar to the embodiment illustrated in FIG. 6, the first crack test resistor RL1 may correspond to a first test pattern H1 of FIG. 6, a second test pattern H2 of FIG. 6, and a connecting portion between the first test pattern H1 and the second test pattern H2. The second crack test resistor RL2 may correspond to the second test pattern H2 of FIG. 6, a third test pattern H3 of FIG. 6, and a connecting portion between the second test pattern H2 and the third test pattern H3. The third crack test resistor RL3 may correspond to the third test pattern H3 of FIG. 6, a fourth test pattern H4 of FIG. 6, and a connecting portion between the third test pattern H3 and the fourth test pattern H4. The display apparatus may be configured to detect the hole crack of the display panel 100.

According to an embodiment, the crack of the display panel 100 may be determined using the test path including the test point TP1, TP2, TP3, and TP4, the driving chip peripheral area of the display panel 100, the driving chip TED, the bending area BE of the display panel 100, and the crack test area of the display panel 100. For example, the sequential structure of the test path ensures that resistance is measured in one or more regions within a single integrated test cycle.

As described above, the crack of the display panel 100 may be accurately and efficiently determined using the auto resistance test method.

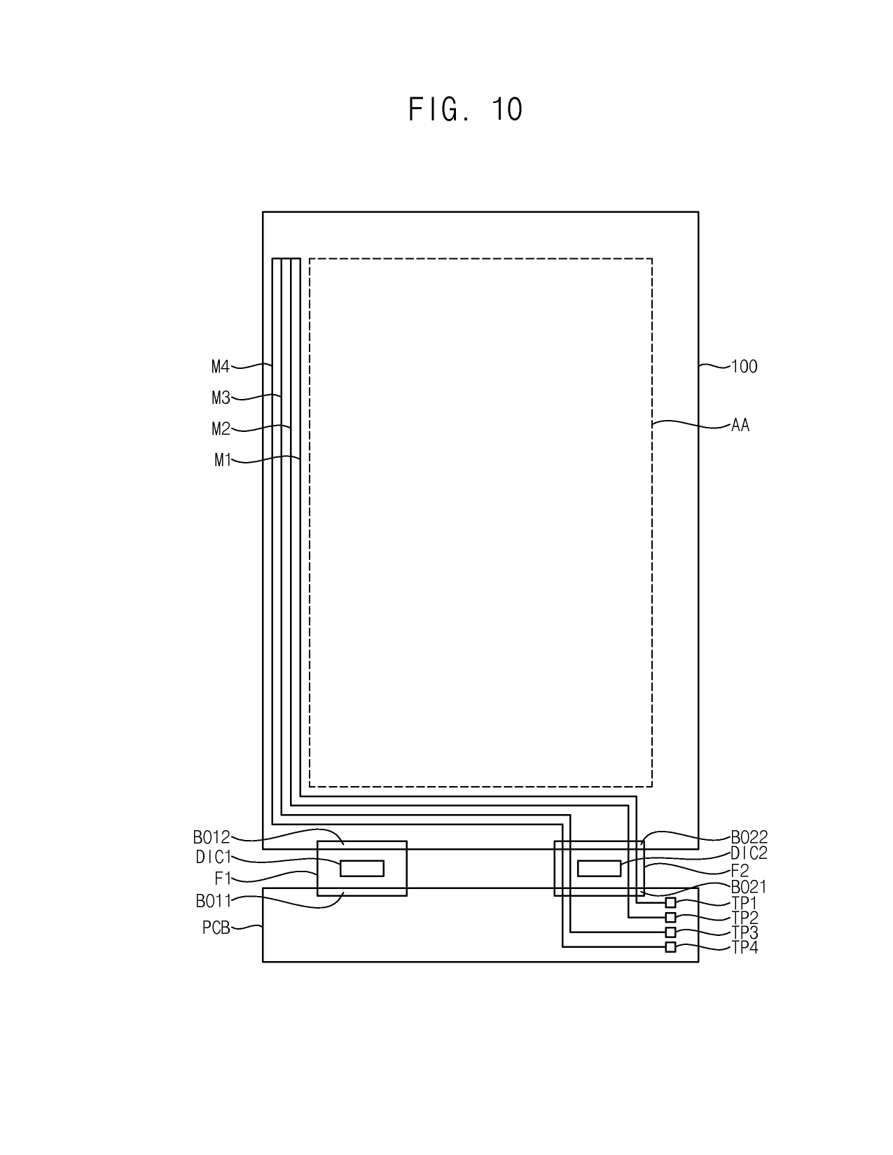

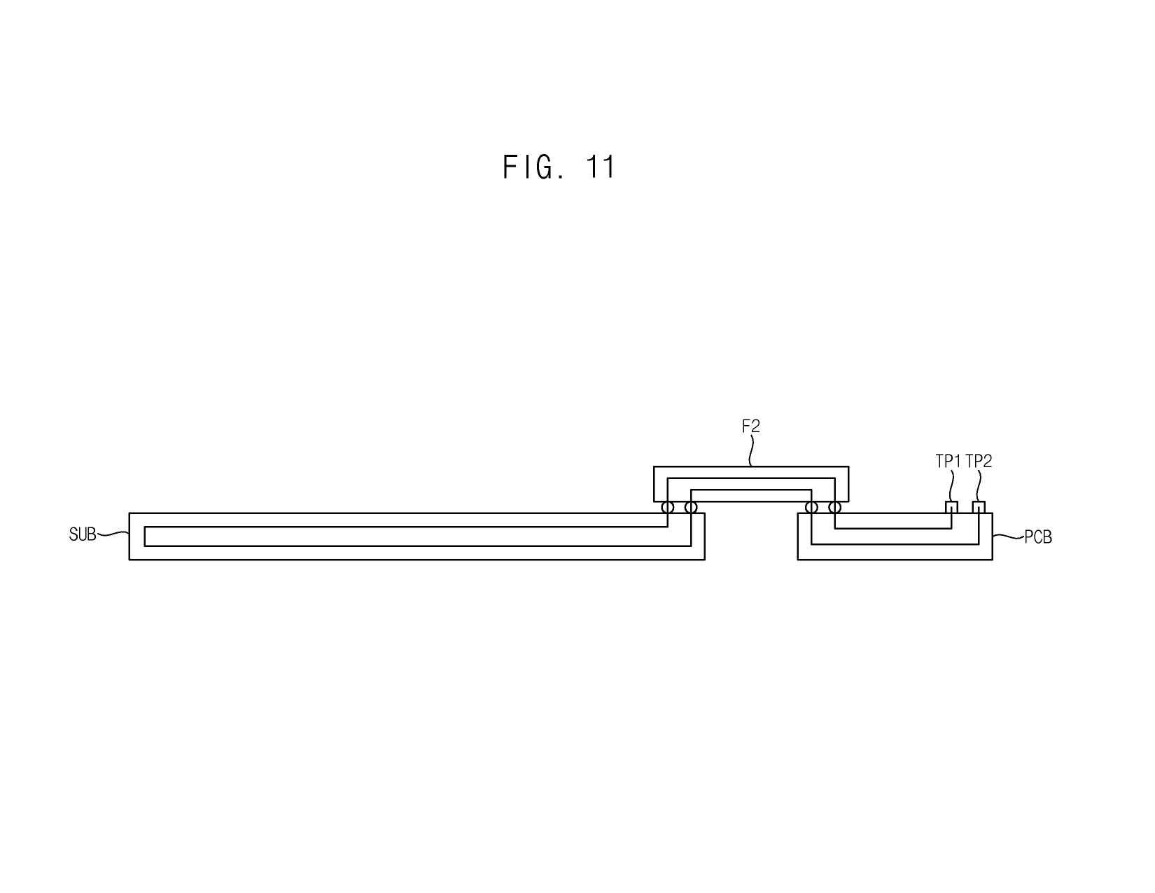

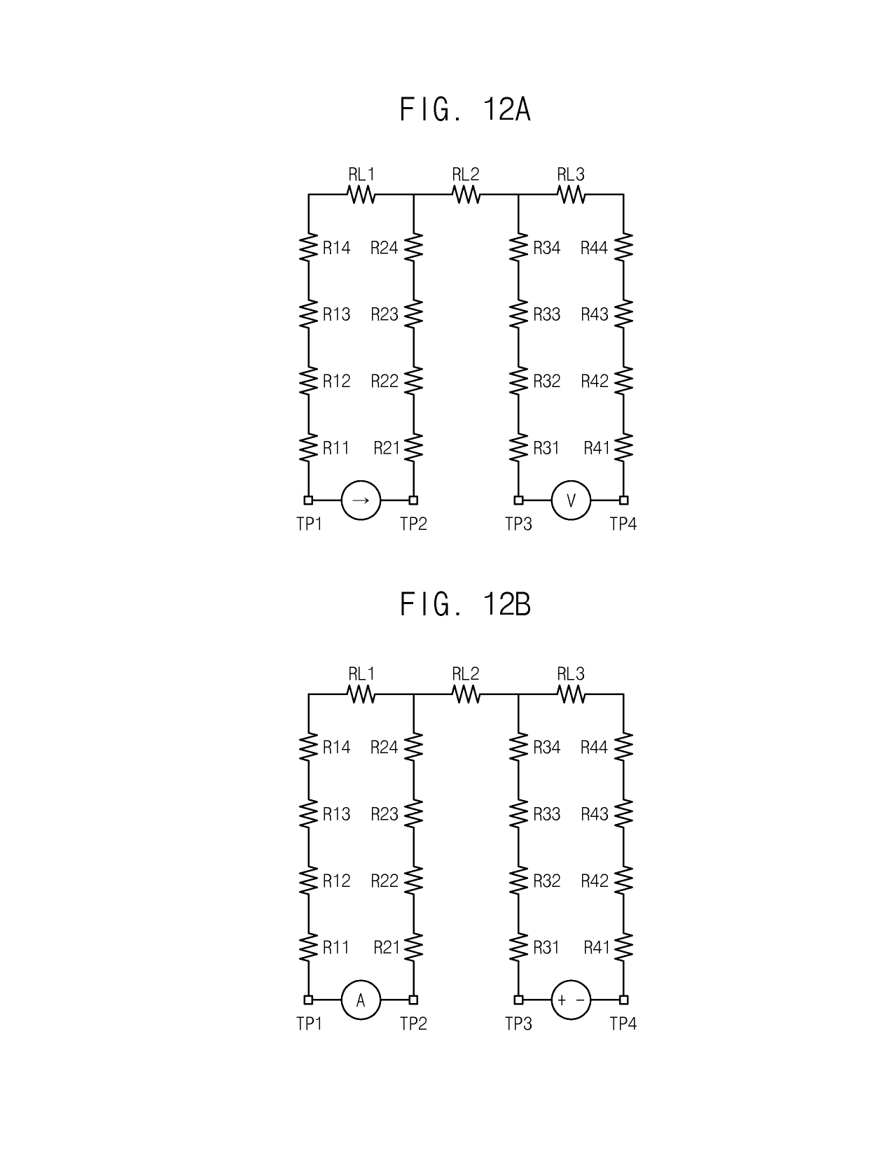

FIG. 10 is a diagram illustrating an example of a display apparatus including a test path configured to determine a first crack of a display panel 100. FIG. 11 is a cross-sectional view illustrating the display apparatus of FIG. 10 including the test path of FIG. 10. FIG. 12A is an example of a circuit diagram illustrating the test path of FIG. 10. FIG. 12B is an example of a circuit diagram illustrating the test path of FIG. 10. As shown in FIG. 10, the test path extends through bonding areas (BO11, BO12, BO21, BO22), data driving chip (DIC1, DIC2), and flexible circuit board (F1, F2), which are not present in the earlier embodiment.

The display apparatus is substantially the same as the display apparatus of the previous embodiment illustrated in FIGS. 1 to 4B except that the display apparatus further includes a flexible circuit board on which the driving chip is mounted, and except for the modified test path formed through the flexible circuit board. Thus, the same reference numerals are used to refer to the same or like parts as those described in the previous embodiment of FIGS. 1 to 4B and differences may be further described.

Referring to FIGS. 1 and 10 to 12B, the display apparatus includes the printed circuit board PCB, the display panel 100 and the flexible circuit board F1 and F2. The printed circuit board PCB includes a first bonding area BO11 and BO21 in which the flexible circuit board F1 and F2 are bonded and a plurality of test points TP1, TP2, TP3, and TP4. The display panel 100 includes an active area (also referred to as the display region) AA in which an image is displayed, a second bonding area BO12 and BO22 in which the flexible circuit board F1 and F2 is bonded and a crack test area in which test patterns M1, M2, M3, and M4 for a crack test are disposed. The flexible circuit board F1 and F2 is bonded at the first bonding area BO11 and BO21 and the second bonding area BO12 and BO22. For example, this configuration enables the crack detection test path to bridge between the printed circuit board PCB and the display panel 100 through the flexible circuit board F1 and F2.

The test path includes the test points TP1, TP2, TP3, and TP4, the printed circuit board PDCB, the first bonding area BO11 and BO21, the flexible circuit board F1 and F2, the second bonding area BO12 and BO22, and the crack test area. By extending the test path to the bonding interfaces and the flexible circuits, the test path is able to detect cracks arising from interconnects within these interfaces and circuits.

In an embodiment, the driving chip may be a data driving chip DIC1 and DIC2 configured to perform an operation of the data driver 500.

The plurality of test points may include a first test point TP1, a second test point TP2, a third test point TP3, and a fourth test point TP4.

As shown in FIG. 12A, a current source may be connected to the first test point TP1 and the second test point TP2. A voltmeter may be connected to the third test point TP3 and the fourth test point TP4. For example, a test signal may be a test voltage measured by the voltmeter.

In an embodiment, as shown in FIG. 12B, an ammeter may be connected to the first test point TP1 and the second test point TP2. A voltage source may be connected to the third test point TP3 and the fourth test point TP4. For example, the test signal may be a test current measured by the ammeter.

As shown in FIGS. 11, 12A and 12B, the test path may include a first resistor R11 connected to the first test point TP1 and corresponding to the printed circuit board PCB, a second resistor R12 connected to the first resistor R11 and corresponding to an first adhesive material disposed in the first bonding area BO21, a third resistor R13 connected to the second resistor R12 and corresponding to the flexible circuit board F2, a fourth resistor R14 connected to the third resistor R13 and corresponding to a second adhesive material disposed in the second bonding area BO22. The test path may include a fifth resistor R21 connected to the second test point TP2 and corresponding to the printed circuit board PCB, a sixth resistor R22 connected to the fifth resistor R21 and corresponding to a third adhesive material disposed in the first bonding area BO21, a seventh resistor R23 connected to the sixth resistor R22 and corresponding to the flexible circuit board F2, an eighth resistor R24 connected to the seventh resistor R23 and corresponding to a fourth adhesive material disposed in the second bonding area BO22. The test path may include a ninth resistor R31 connected to the third test point TP3 and corresponding to the printed circuit board PCB, a tenth resistor R32 connected to the ninth resistor R31 and corresponding to a fifth adhesive material disposed in the first bonding area BO21, an eleventh resistor R33 connected to the tenth resistor R32 and corresponding to the flexible circuit board F2, a twelfth resistor R34 connected to the eleventh resistor R33 and corresponding to a sixth adhesive material disposed in the second bonding area BO22. The test path may include a thirteenth resistor R41 connected to the fourth test point TP4 and corresponding to the printed circuit board PCB, a fourteenth resistor R42 connected to the thirteenth resistor R41 and corresponding to a seventh adhesive material disposed in the first bonding area BO21, a fifteenth resistor R43 connected to the fourteenth resistor R42 and corresponding to the flexible circuit board F2, a sixteenth resistor R44 connected to the fifteenth resistor R43 and corresponding to an eighth adhesive material disposed in the second bonding area BO22. The test path may include a first crack test resistor RL1 connected between the fourth resistor R14 and the eighth resistor R24 and corresponding to the crack test area, a second crack test resistor RL2 connected between the eighth resistor R24 and the twelfth resistor R34 and corresponding to the crack test area, and a third crack test resistor RL3 connected between the twelfth resistor R34 and the sixteenth resistor R44 and corresponding to the crack test area.

As shown in FIG. 10, the first crack test resistor RL1 may correspond to a first test pattern M1 of FIG. 10, a second test pattern M2 of FIG. 10, and a connecting portion between the first test pattern M1 and the second test pattern M2. The second crack test resistor RL2 may correspond to the second test pattern M2 of FIG. 10, a third test pattern M3 of FIG. 10, and a connecting portion between the second test pattern M2 and the third test pattern M3. The third crack test resistor RL3 may correspond to the third test pattern M3 of FIG. 10, a fourth test pattern M4 of FIG. 10, and a connecting portion between the third test pattern M3 and the fourth test pattern M4. The display apparatus may be configured to detect the module crack of the display panel 100.

In an embodiment, similar to the embodiment illustrated in FIG. 6, the first crack test resistor RL1 may correspond to a first test pattern H1 of FIG. 6, a second test pattern H2 of FIG. 6, and a connecting portion between the first test pattern H1 and the second test pattern H2. The second crack test resistor RL2 may correspond to the second test pattern H2 of FIG. 6, a third test pattern H3 of FIG. 6, and a connecting portion between the second test pattern H2 and the third test pattern H3. The third crack test resistor RL3 may correspond to the third test pattern H3 of FIG. 6, a fourth test pattern H4 of FIG. 6, and a connecting portion between the third test pattern H3 and the fourth test pattern H4. The display apparatus may be configured to detect the hole crack of the display panel 100.

According to an embodiment, the crack of the display panel 100 may be determined using the test path sequentially including the test point TP1, TP2, TP3, and TP4, the printed circuit board PCB, the first bonding area BO21 of the printed circuit board PCB, the flexible circuit board F2, the second bonding area BO22 of the display panel 100, and the crack test area of the display panel 100. This sequential configuration ensures that cracks arising at any region of the display device, such as from the PCB interface through the bonding layers and flexible circuit up to the panel crack test area, can be detected in a single continuous resistance measurement.

As described above, the crack of the display panel 100 may be accurately and efficiently determined using the auto resistance test method. For example, the integration of the flexible circuit boards (F1, F2) and bonding interfaces into the test path may further enhance crack detection within the display panel 100.

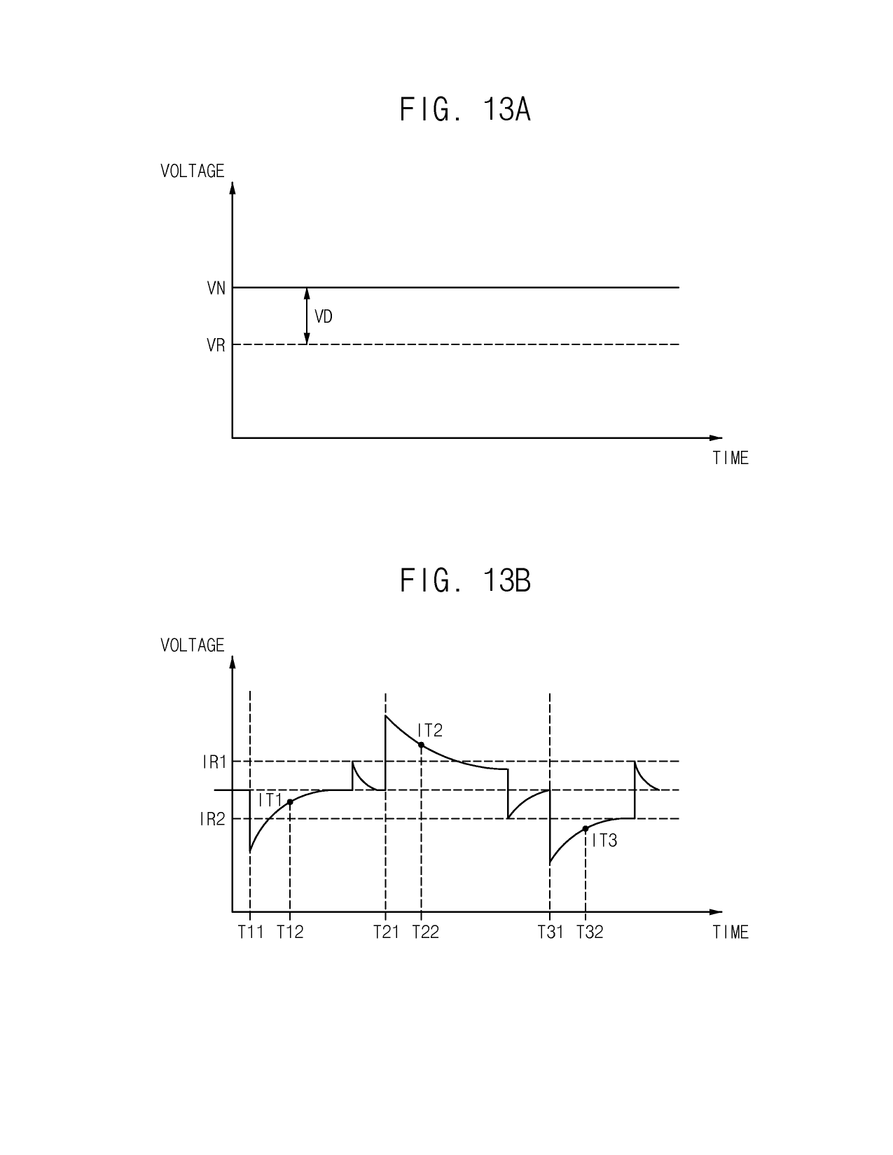

FIG. 13A is a graph illustrating a method for determining a crack in a display apparatus according to an embodiment of the present inventive concept. FIG. 13B is a graph illustrating a method for determining a crack in a display apparatus according to an embodiment of the present inventive concept. FIG. 13C is a graph illustrating a method for determining a crack in a display apparatus according to an embodiment of the present inventive concept. FIG. 13D is a graph illustrating a method for determining a crack in a display apparatus according to an embodiment of the present inventive concept.

FIGS. 13A to 13D illustrate examples of a method for determining a crack of the display panel 100 based on a test voltage or a test current. The method may be implemented in hardware, software, or a combination thereof within the display apparatus or an external test controller.

Referring to FIG. 13A, the test signal received through the test points TP1, TP2, TP3, and TP4 may be the test voltage. When the test voltage is less than a predetermined reference voltage VR which is less than a normal voltage VN, a crack of the display panel 100 may be detected. The reference voltage VR may be less than the normal voltage VN by a threshold voltage difference VD. The threshold voltage difference VD may be set to a predetermined value to detect the crack. For example, the threshold voltage difference VD may be adjusted based on the panel size or material properties of the display panel.

Referring to FIG. 13B, the test signal received through the test points TP1, TP2, TP3, and TP4 may be the test current. When the test current is out of a range between a first reference current IR1 and a second reference current IR2 at a test time point in a determining cycle, a crack of the display panel 100 may be detected.

A test current IT1 is in the range between the first reference current IR1 and the second reference current IR2 at a first test time point T12 in a first determining cycle T11 to T21 so that the display panel 100 may be determined to be in a normal state in the first determining cycle T11 to T21.

A test current IT2 is out of the range between the first reference current IR1 and the second reference current IR2 at a second test time point T22 in a second determining cycle T21 to T31. Thus, the display apparatus may determine that the display panel 100 has a crack in the second determining cycle T21 to T31.

A test current IT3 is out of the range between the first reference current IR1 and the second reference current IR2 at a third test time point T32 in a third determining cycle (after T31). Thus, the display apparatus may determine that the display panel 100 has a crack in the third determining cycle (after T31).

Referring to FIG. 13C, when the test signal received through the test point TP1, TP2, TP3, and TP4 does not exceed a reference signal SR in a determining cycle, or exceeds the reference signal SR two or more times in the determining cycle, a crack of the display panel 100 may be detected. However, the number of times that the test signal exceeds the reference signal SR is not necessarily limited thereto.

A level of the test signal is less than a level of the reference signal SR in a first determining cycle of FIG. 13C, the display apparatus may determine that the display panel 100 has a crack in the first determining cycle.

The level of the test signal is greater than the level of the reference signal SR and the level of the test signal exceeds the level of the reference signal SR once in a second determining cycle of FIG. 13C so that the display panel 100 may be determined as a normal state in the second determining cycle.

The level of the test signal exceeds the level of the reference signal SR twice in a third determining cycle of FIG. 13C so the display apparatus may determine that the display panel 100 has a crack in the third determining cycle.

The level of the test signal is less than the level of the reference signal SR (the test signal is not received) in a fourth determining cycle of FIG. 13C so the display apparatus may determine the display panel 100 has a crack in the fourth determining cycle.

The level of the test signal is greater than the level of the reference signal SR and the level of the test signal exceeds the level of the reference signal SR once in a fifth determining cycle of FIG. 13C so that the display panel 100 may be determined as the normal state in the fifth determining cycle.

Referring to FIG. 13D, the crack of the display panel 100 may be detected by a test circuit.

For example, the test circuit may include a reference resistor RR including a first electrode receiving a reference signal REF and a second electrode connected to a first node, and a transistor TR. The transistor TR may include a control electrode that receives a test signal INVI received through the test point TP1, TP2, TP3, and TP4, a first electrode connected to the first node, and a second electrode connected to a ground. The crack of the display panel 100 may be detected based on a signal of the first node.

The test circuit may be an inverter circuit. When the test signal INVI exceeds a predetermined value, an output INVO of the inverter circuit may be inverted and output. Thus, even without visually checking the test signal, the crack of the display panel 100 may be determined using the test circuit.

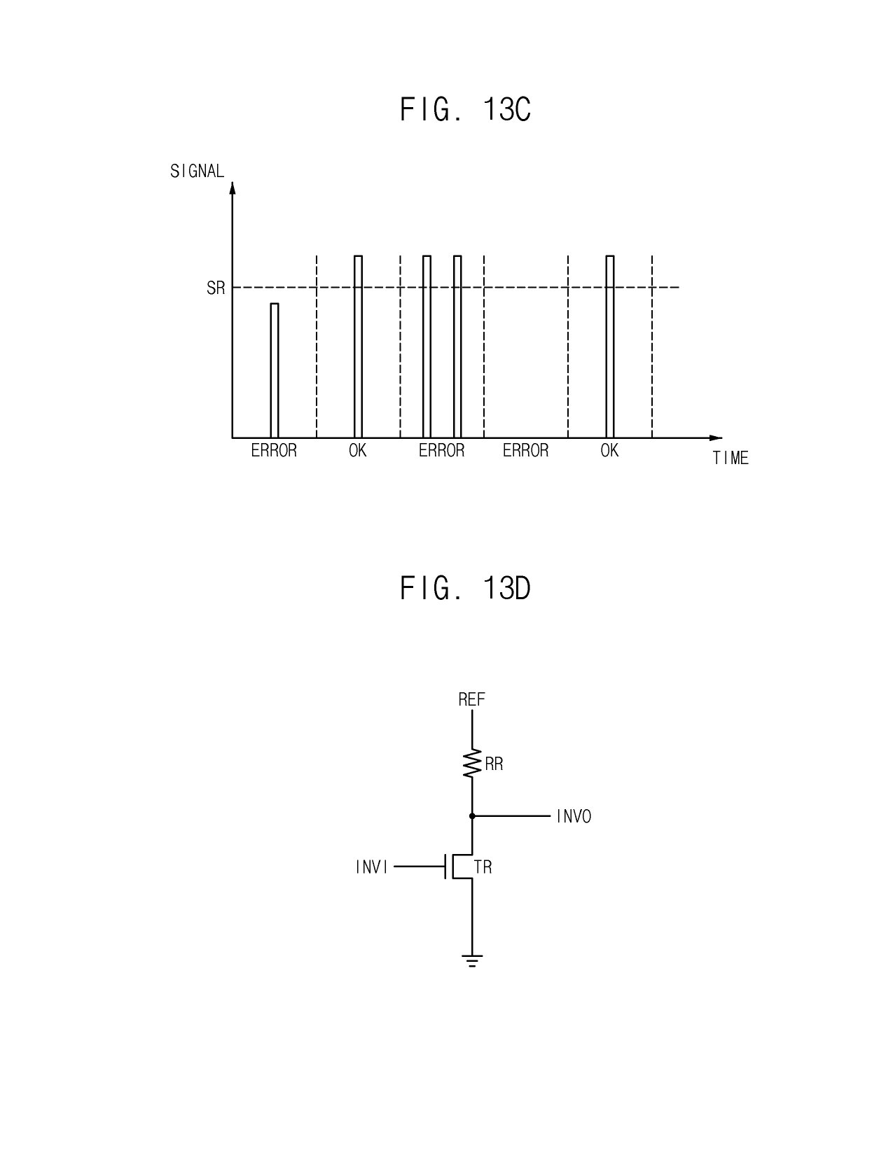

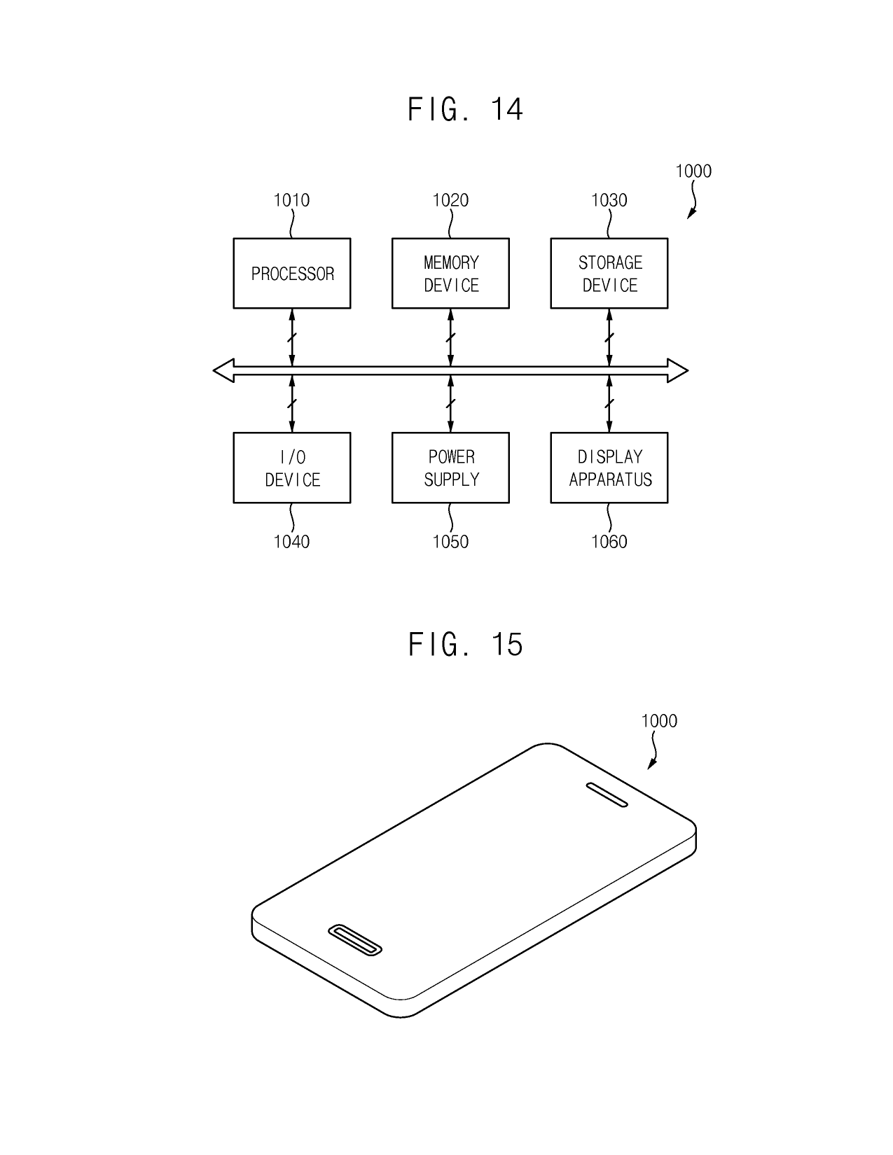

FIG. 14 is a block diagram illustrating an electronic apparatus 1000 according to an embodiment of the present inventive concept. FIG. 15 is a diagram illustrating an example in which the electronic apparatus 1000 of FIG. 14 is implemented as a smartphone.

Referring to FIGS. 14 and 15, the electronic apparatus 1000 may include a processor 1010, a memory device 1020, a storage device 1030, an input/output (I/O) device 1040, a power supply 1050, and a display apparatus 1060. For example, the display apparatus 1060 may be the display apparatus of FIG. 1. In addition, the electronic apparatus 1000 may further include a plurality of ports for communicating with a video card, a sound card, a memory card, a universal serial bus (USB) device, or other external electronic apparatuses.

In an embodiment, as illustrated in FIG. 15, the electronic apparatus 1000 may be implemented as a smartphone. However, the electronic apparatus 1000 is not necessarily limited thereto. For example, the electronic apparatus 1000 may be implemented as a television, a cellular phone, a monitor, a video phone, a smart pad, a smart watch, a tablet computer, a car navigation system, a laptop, a head mounted display (HMD) device, or other electronic devices.

The processor 1010 may perform various computing functions or various tasks. The processor 1010 may be a micro-processor, a central processing unit (CPU), an application processor (AP), or other processing units. The processor 1010 may be coupled to other components via an address bus, a control bus, a data bus, or a combination thereof. In some cases, the processor 1010 may be coupled to an extended bus such as a peripheral component interconnection (PCI) bus.

The processor 1010 may output the input image data IMG and the control signal CONT to the driving controller 200 of the display panel driver of FIG. 1.

The memory device 1020 may store data for operations of the electronic apparatus 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, and/or at least one volatile memory device such as a dynamic random access memory (DRAM) device, a static random access memory (SRAM) device, a mobile DRAM device, or other volatile memory devices.

The storage device 1030 may include a solid-state drive (SSD) device, a hard disk drive (HDD) device, a CD-ROM device, or other mass storage devices. The I/O device 1040 may include an input device such as a keyboard, a keypad, a mouse device, a touch-pad, a touch-screen, or other input devices and an output device such as a printer, a speaker, or other output devices. In some embodiments, the display apparatus 1060 may be included in the I/O device 1040. The power supply 1050 may provide power for operations of the electronic apparatus 1000. The display apparatus 1060 may be coupled to other components via the buses or other communication links.

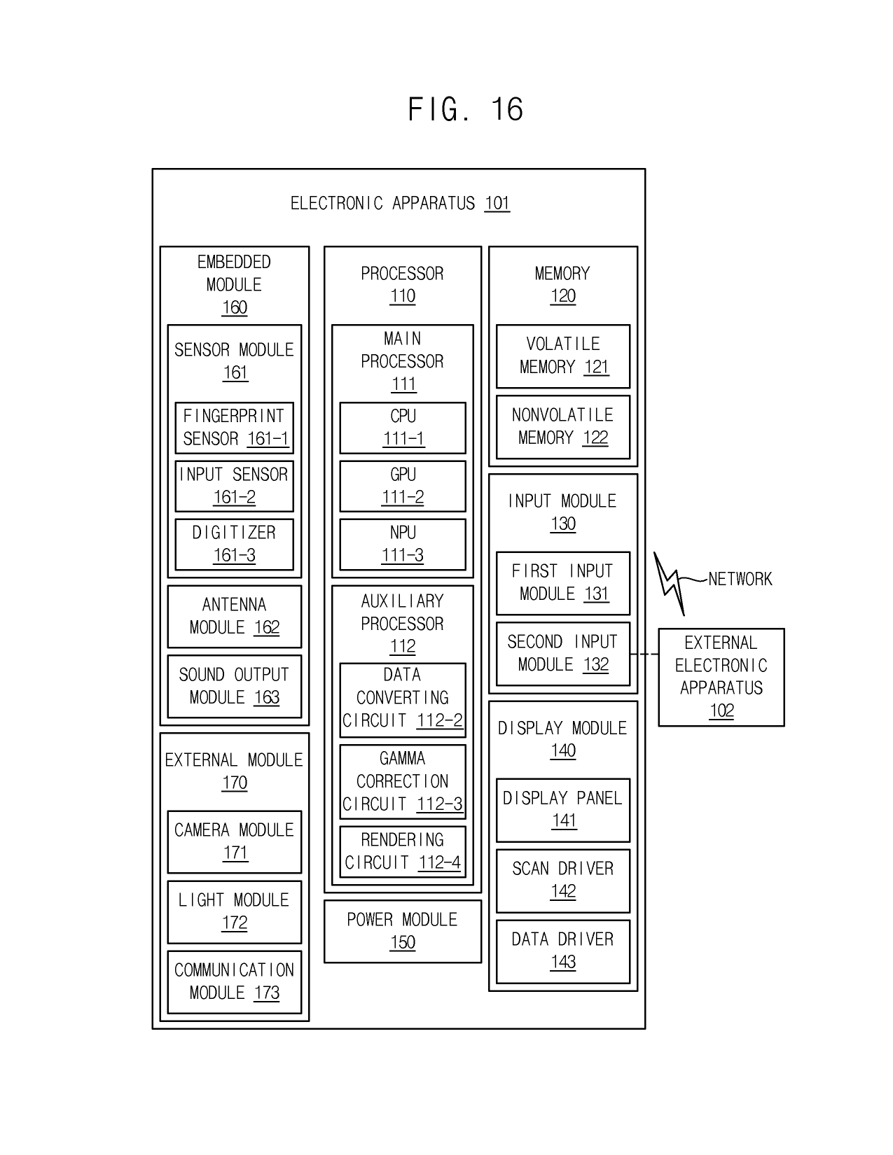

FIG. 16 is a block diagram illustrating an electronic apparatus 101 according to an embodiment of the present inventive concept.

Referring to FIGS. 1 to 16, the electronic apparatus 101 outputs various information through a display module 140 operating under control of an operating system. When a processor 110 executes an application stored in a memory 120, the display module 140 provides application information to a user through a display panel 141.

The processor 110 obtains an input signal through an input module 130 or a sensor module 161 and executes an application corresponding to the input signal. For example, when the user selects a camera icon displayed on the display panel 141, the processor 110 obtains a user input through an input sensor 161-2 and activates a camera module 171. The processor 110 transfers image data corresponding to a captured image obtained through the camera module 171 to the display module 140. The display module 140 may display an image corresponding to the captured image through the display panel 141. In an embodiment, the processor 110 may simultaneously transfer captured image data to an external electronic apparatus 102 through the communication module 173 for cloud storage or remote monitoring.

In an embodiment, when a personal information authentication is executed in the display module 140, a fingerprint sensor 161-1 obtains input fingerprint information as input data. The processor 110 compares input data obtained through the fingerprint sensor 161-1 with authentication data stored in the memory 120, and executes an application based on a comparison result. The display module 140 may display information executed based on application logic through the display panel 141.

In an embodiment, when a music streaming icon displayed on the display module 140 is selected, the processor 110 obtains a user input through the input sensor 161-2 and activates a music streaming application stored in the memory 120. When a music execution command is input in the music streaming application, the processor 110 activates a sound output module 163 to provide sound information corresponding to the music execution command to the user.

Hereinafter, a configuration of the electronic apparatus 101 is described in detail. Some of elements of the electronic apparatus 101 described later may be integrated and provided as one element, or one element may be separated as two or more elements.

The electronic apparatus 101 may communicate with an external electronic apparatus 102 through a network (e.g. a short-range wireless communication network or a long-range wireless communication network). According to an embodiment, the electronic apparatus 101 may include the processor 110, the memory 120, the input module 130, the display module 140, a power module 150, an embedded module 160, and an external module 170. According to an embodiment, in the electronic apparatus 101, at least one of the above-described elements might not be included or one or more additional apparatuses may be included. According to an embodiment, some of the above-described elements (e.g., the sensor module 161, an antenna module 162 or the sound output module 163) may be integrated into another element (e.g. the display module 140).

The processor 110 may execute software to control at least one other element (e.g. hardware or software element) of the electronic apparatus 101 connected to the processor 110 and to perform various data processing or operations. According to an embodiment, as at least part of the data processing or the operations, the processor 110 may store receive instructions or data from other elements (e.g. the input module 130, the sensor module 161 or a communication module 173) in a volatile memory 121, may process the instructions or data stored in the volatile memory 121 and may store result data of the processing in a nonvolatile memory 122.

The processor 110 may include a main processor 111 and an auxiliary processor 112. The main processor 111 may include at least one of a central processing unit (CPU) 111-1 and an application processor (AP). The main processor 111 may further include any one or more of a graphic processing unit (GPU) 111-2, a communication processor (CP) and an image signal processor (ISP). The main processor 111 may further include a neural processing unit (NPU) 111-3. The NPU 111-3 is a processor specialized in processing an artificial intelligence model. The artificial intelligence model may be generated through a machine learning. The artificial intelligence model may include a plurality of artificial neural network layers. The artificial neural network may include at least one of a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-networks, or a combination thereof. However, the artificial neural network is not necessarily limited to the above examples. The artificial intelligence model may include software structures, in addition to hardware structures or instead of the hardware structures. At least two of the above-described processing units and the above-described processors may be implemented as an integrated element (e.g. a single chip) or each may be implemented as independent elements (e.g. in a plurality of chips).

The auxiliary processor 112 may include a controller. The controller may include an interface conversion circuit and a timing control circuit. The controller receives an image signal from the main processor 111, converts a data format of the image signal to meet interface specifications with the display module 140, and outputs image data. The controller may output various control signals for driving the display module 140.

The auxiliary processor 112 may further include a data converting circuit 112-2, a gamma correction circuit 112-3, and a rendering circuit 112-4. The data converting circuit 112-2 may receive the image data from the controller and may compensate the image data such that the image is displayed with a target luminance based on characteristics of the electronic apparatus 101, a user setting, or may convert the image data to reduce a power consumption or compensate for afterimages. The gamma correction circuit 112-3 may convert the image data or a gamma reference voltage such that the image displayed on the electronic apparatus 101 has target gamma characteristics. The rendering circuit 112-4 may receive the image data from the controller and may render the image data based on a pixel arrangement of the display panel 141 included in the electronic apparatus 101. At least one of the data converting circuit 112-2, the gamma correction circuit 112-3, and the rendering circuit 112-4 may be integrated into another element (e.g. the main processor 111 or the controller). At least one of the data converting circuit 112-2, the gamma correction circuit 112-3, and the rendering circuit 112-4 may be integrated into a data driver 143 to be described later.

The memory 120 may store various data used by at least one element (e.g. the processor 110 or the sensor module 161) of the electronic apparatus 101 and input data or output data for commands related thereto. The memory 120 may include at least one of the volatile memory 121 and the nonvolatile memory 122.

The input module 130 may receive commands or data used to the elements (e.g. the processor 110, the sensor module 161, or the sound output module 163) of the electronic apparatus 101 from the outside of the electronic apparatus 101 (e.g. the user or the external electronic apparatus 102).

The input module 130 may include a first input module 131 for receiving commands or data from the user and a second input module 132 for receiving commands or data from the external electronic apparatus 102. The first input module 131 may include a microphone, a mouse, a keyboard, a key (e.g. a button), or a pen (e.g. a passive pen or an active pen). The second input module 132 may support a designated protocol capable of connecting to the external electronic apparatus 102 by wire or wirelessly. According to an embodiment, the second input module 132 may include a high-definition multimedia interface (HDMI), a universal serial bus (USB) interface, an SD card interface, or an audio interface. The second input module 132 may include a connector physically connected to the external electronic apparatus 102, for example, an HDMI connector, a USB connector, an SD card connector, or an audio connector (e.g. a headphone connector).

The display module 140 visually provides information to the user. The display module 140 may include the display panel 141, a scan driver 142, and the data driver 143. The display module 140 may further include a window, a chassis, and a bracket to protect the display panel 141.

The display panel 141 may include a liquid crystal display panel, an organic light emitting display panel, or an inorganic light emitting display panel. A type of the display panel 141 is not necessarily limited thereto. The display panel 141 may be a rigid type or a flexible type capable of being rolled or folded. The display module 140 may further include a supporter or a heat dissipation member supporting the display panel 141.

The scan driver 142 may be mounted on the display panel 141 as a driving chip. In an embodiment, the scan driver 142 may be integrated on the display panel 141. For example, the scan driver 142 may include an amorphous silicon TFT gate driver circuit (ASG) integrated on the display panel 141, a low temperature polycrystalline silicon (LTPS) TFT gate driver circuit integrated on the display panel 141, or an oxide semiconductor TFT gate driver circuit (OSG) integrated on the display panel 141. The scan driver 142 receives a control signal from the controller and outputs the scan signals to the display panel 141 in response to the control signal.

The display module 140 may further include a light emission driver. The light emission driver outputs a light emission control signal to the display panel 141 in response to a control signal received from the controller. The light emission driver may be formed independently from the scan driver 142. In an embodiment, the light emission driver and the scan driver 142 may be integrally formed.

The data driver 143 receives a control signal from the controller, converts the image data into an analog voltage (e.g. the data voltage), and output the data voltages to the display panel 141 in response to the control signal.

The data driver 143 may be integrated into another element (e.g. the controller). The functions of the interface conversion circuit and the timing control circuit of the controller described above may be integrated into the data driver 143.

The display module 140 may further include a voltage generating circuit. The voltage generating circuit may output various voltages for driving the display panel 141.

The power module 150 supplies power to elements of the electronic apparatus 101. The power module 150 may include a battery which supplies a power voltage. The battery may include a non-rechargeable primary cell, a rechargeable secondary cell, or a fuel cell. The power module 150 may include a power management integrated circuit (PMIC). The PMIC supplies optimized power to each of the above-described modules and modules described later. The power module 150 may include a wireless power transmission/reception member electrically connected to the battery. The wireless power transmission/reception member may include a plurality of antenna radiators in a form of coils.

The electronic apparatus 101 may further include the embedded module 160 and the external module 170. The embedded module 160 may include the sensor module 161, the antenna module 162, and the sound output module 163. The external module 170 may include the camera module 171, a light module 172, and the communication module 173.

The sensor module 161 may detect an input by a body part of a user or an input by the pen among the first input module 131, and generate an electrical signal or data value corresponding to the input. The sensor module 161 may include at least one of the fingerprint sensor 161-1, the input sensor 161-2, and a digitizer 161-3.

The fingerprint sensor 161-1 may generate a data value corresponding to a user’s fingerprint. The fingerprint sensor 161-1 may include one of an optical fingerprint sensor or a capacitive fingerprint sensor.

The input sensor 161-2 may generate data values corresponding to coordinate information of the input by the user’s body or the input by the pen. The input sensor 161-2 generates a capacitance change due to an input as a data value. The input sensor 161-2 may detect an input by the passive pen or transmit/receive data to/from the active pen.

The input sensor 161-2 may measure biosignals such as a blood pressure, a moisture, or a body fat. For example, when a user contacts a part of the body with a sensor layer or a sensing panel and does not move for a certain period of time, the input sensor 161-2 may detect the biosignal based on a change in an electric field caused by the part of the body so that the display module 140 may output information of the user.

The digitizer 161-3 may generate a data value corresponding to the coordinate information input by the pen. The digitizer 161-3 generates an amount of electromagnetic change by the input as a data value. The digitizer 161-3 may detect an input by the passive pen or transmit/receive data to/from the active pen.

At least one of the fingerprint sensor 161-1, the input sensor 161-2, and the digitizer 161-3 may be formed as a sensor layer on the display panel 141 through a continuous process. The fingerprint sensor 161-1, the input sensor 161-2, and the digitizer 161-3 may be disposed on the display panel 141. At least one of the fingerprint sensor 161-1, the input sensor 161-2, and the digitizer 161-3 may be disposed under the display panel 141. For example, the digitizer 161-3 may be disposed under the display panel 141.

At least two or more of the fingerprint sensor 161-1, the input sensor 161-2, and the digitizer 161-3 may be integrated into the sensing panel through the same process. When at least two or more of the fingerprint sensor 161-1, the input sensor 161-2, and the digitizer 161-3 are integrated into the sensing panel, the sensing panel may be disposed between the display panel 141 and a window disposed over an upper surface of the display panel 141. According to an embodiment, the sensing panel may be disposed on the window. The present inventive concept not necessarily limited to a position of the sensing panel.

At least one of the fingerprint sensor 161-1, the input sensor 161-2, and the digitizer 161-3 may be embedded in the display panel 141. For example, at least one of the fingerprint sensor 161-1, the input sensor 161-2, and the digitizer 161-3 is formed simultaneously with the display panel 141 through a process of forming elements included in the display panel 141 (e.g. light emitting elements, transistors, etc.).

In addition, the sensor module 161 may generate an electrical signal or a data value corresponding to an internal state or an external state of the electronic apparatus 101. For example, the sensor module 161 may further include a gesture sensor, a gyro sensor, a barometric pressure sensor, a magnetic sensor, an acceleration sensor, a grip sensor, a proximity sensor, a color sensor, an IR (infrared) sensor, a biosensor, a temperature sensor, a humidity sensor or an illuminance sensor.

The antenna module 162 may include one or more antennas for transmitting a signal or power to outside or receiving a signal or power from outside. According to an embodiment, the communication module 173 may transmit a signal to an external electronic apparatus or receive a signal from an external electronic apparatus through an antenna suitable for a communication method. An antenna pattern of the antenna module 162 may be integrated with an element of the display module 140 (e.g. the display panel 141) or the input sensor 161-2.

The sound output module 163 is a device for outputting sound signals to the outside of the electronic apparatus 101. For example, the sound output module 163 may include a speaker used for general purposes such as playing multimedia or recording and a receiver used exclusively for receiving a call. According to an embodiment, the receiver may be formed integrally with or separately from the speaker. A sound output pattern of the sound output module 163 may be integrated with the display module 140.

The camera module 171 may capture still images and moving images (e.g., a video). According to an embodiment, the camera module 171 may include one or more lenses, an image sensor, or an image signal processor. The camera module 171 may further include an infrared camera capable of determining a presence or an absence of a user, the location of the user, and the gaze of the user.

The light module 172 may provide a light. The light module 172 may include a light emitting diode or a xenon lamp. The light module 172 may operate in conjunction with the camera module 171 or operate independently.

The communication module 173 may support establishment of a wired or wireless communication channel between the electronic apparatus 101 and the external electronic apparatus 102 and communication through the established communication channel. The communication module 173 may include one or both of a wireless communication module such as a cellular communication module, a short-distance wireless communication module, or a global navigation satellite system (GNSS) communication module, and a wired communication module such as a local area network (LAN) communication module, or a power line communication module. The communication module 173 may communicate with the external electronic apparatus 102 through a short-range communication network such as Bluetooth, WiFi direct, or infrared data association (IrDA). The communication module 173 may communicate with the external electronic apparatus 102 through a long-distance communication network such as a cellular network, the Internet, or a computer network (e.g. LAN or WAN). The various types of communication module 173 described above may be implemented as a single chip or may be implemented as separate chips.

The input module 130, the sensor module 161, and the camera module 171 may be used to control the operation of the display module 140 in conjunction with the processor 110.

The processor 110 outputs commands or data to the display module 140, the sound output module 163, the camera module 171, or the light module 172 based on the input data received from the input module 130. For example, the processor 110 may generate image data corresponding to input data applied through a mouse or an active pen, and output the generated image data to the display module 140 or the processor 110 may generate command data corresponding to the input data and output the generated command data to the camera module 171 or the light module 172. When input data is not received from the input module 130 for a certain period of time, the processor 110 converts an operation mode of the electronic apparatus 101 into a low power mode or a sleep mode so that a power consumption of the electronic apparatus 101 may be reduced.

The processor 110 outputs commands or data to the display module 140, the sound output module 163, the camera module 171, or the light module 172 based on sensed data received from the sensor module 161. For example, the processor 110 may compare authentication data applied by the fingerprint sensor 161-1 with authentication data stored in the memory 120, and then execute an application based on the comparison result. The processor 110 may execute commands or output corresponding image data to the display module 140 based on the sensed data sensed by the input sensor 161-2 or the digitizer 161-3. When the sensor module 161 includes a temperature sensor, the processor 110 may receive temperature data for the temperature measured from the sensor module 161, and may further perform luminance correction on the image data based on the temperature data.

The processor 110 may receive determined data about the presence or the absence of the user, the location of the user, and the gaze of the user from the camera module 171. The processor 110 may further perform luminance correction on the image data based on the determined data. For example, the processor 110, which determines the presence or the absence of the user through an input from the camera module 171, may display image data having the luminance corrected by the data converting circuit 112-2 or the gamma correction circuit 112-3 to the display module 140.

Some of the above elements may be connected to each other through a communication method between peripheral devices such as a bus, a general purpose input/output (GPIO), a serial peripheral interface (SPI), a mobile industry processor interface (MIPI), or a ultra path interconnect (UPI) link to exchange signals (e.g. commands or data) with each other. The processor 110 may communicate with the display module 140 through an agreed interface. For example, the processor 110 may communicate with the display module 140 through any one of the above communication methods. The present invention not necessarily limited to the above communication methods.

The electronic apparatus 101 according to various embodiments disclosed in the disclosure may be various types of apparatuses. For example, the electronic apparatus 101 may include at least one of a portable communication apparatus (e.g. a smartphone), a computer apparatus, a portable multimedia apparatus, a portable medical apparatus, a camera, a wearable device, and a home appliance. The electronic apparatus 101 according to the embodiment of the disclosure is not necessarily limited to the aforementioned apparatuses.

For example, the display panel 100 of FIG. 1 may correspond to the display panel 141 of FIG. 16. For example, the driving controller 200 of FIG. 1 may correspond to the controller of the auxiliary processor 112 of FIG. 16. For example, the gate driver 300 of FIG. 1 may correspond to the scan driver 142 of FIG. 16. For example, the data driver 500 of FIG. 1 may correspond to the data driver 143 of FIG. 16.

According to the display apparatus and the electronic apparatus described above, the crack of the display panel may be accurately and efficiently determined using the auto resistance test method.

The foregoing is illustrative of the present inventive concept and is not to be construed as limiting thereof. Although a number embodiments of the present inventive concept have been described, those skilled in the art will readily appreciate that many modifications are possible in the embodiments without materially departing from the scope and technical spirit of the present inventive concept. Accordingly, all such modifications are intended to be included within the scope of the present inventive concept. Therefore, it is to be understood that the foregoing is illustrative of the present inventive concept and is not to be construed as limited to the specific embodiments disclosed, and that modifications to the disclosed embodiments, as well as other embodiments, are intended to be included within the scope of the present disclosure.

What is claimed is:

1. A display apparatus, comprising:
a display panel including an active area configured to display an image, a bending area in which a substrate of the display panel is bent, a bonding area in which a printed circuit board is bonded to the display panel, and a crack test area including a test pattern; and
a plurality of test points disposed on the printed circuit board;
wherein the plurality of test points, the printed circuit board, the bonding area, the bending area, and the crack test area form a test path.

2. The display apparatus of claim 1, wherein:
the plurality of test points includes a first test point, a second test point, a third test point, and a fourth test point.

3. The display apparatus of claim 2, further comprising:
a current source connected to the first test point and the second test point,
a voltmeter connected to the third test point and the fourth test point.

4. The display apparatus of claim 2, further comprising:
an ammeter connected to the first test point and the second test point, and
a voltage source connected to the third test point and the fourth test point.

5. The display apparatus of claim 1, further comprising:
a driving chip mounted on the substrate of the display panel,
wherein the test path includes the plurality of test points, the printed circuit board, the bonding area, a portion of the driving chip, the bending area, and the crack test area.

6. The display apparatus of claim 5, wherein the plurality of test points further include:
a first test point, a second test point, a third test point, and a fourth test point, and
wherein the test path includes:
a first resistor connected to the first test point and corresponding to the printed circuit board; a second resistor connected to the first resistor and corresponding to a first adhesive material disposed in the bonding area; a third resistor connected to the second resistor and corresponding to the substrate of the display panel; a fourth resistor connected to the third resistor and corresponding to the driving chip;
a fifth resistor connected to the second test point and corresponding to the printed circuit board; a sixth resistor connected to the fifth resistor and corresponding to a second adhesive material disposed in the bonding area; a seventh resistor connected to the sixth resistor and corresponding to the substrate of the display panel; an eighth resistor connected to the seventh resistor and corresponding to the driving chip;
a ninth resistor connected to the third test point and corresponding to the printed circuit board; a tenth resistor connected to the ninth resistor and corresponding to a third adhesive material disposed in the bonding area; an eleventh resistor connected to the tenth resistor and corresponding to the substrate of the display panel; a twelfth resistor connected to the eleventh resistor and corresponding to the driving chip;
a thirteenth resistor connected to the fourth test point and corresponding to the printed circuit board; a fourteenth resistor connected to the thirteenth resistor and corresponding to a fourth adhesive material disposed in the bonding area; a fifteenth resistor connected to the fourteenth resistor and corresponding to the substrate of the display panel; a sixteenth resistor connected to the fifteenth resistor and corresponding to the driving chip;
a first crack test resistor connected between the fourth resistor and the eighth resistor and corresponding to the crack test area; a second crack test resistor connected between the eighth resistor and the twelfth resistor and corresponding to the crack test area; and a third crack test resistor connected between the twelfth resistor and the sixteenth resistor and corresponding to the crack test area.

7. The display apparatus of claim 1, wherein:
the crack test area includes a plurality of first crack test patterns disposed adjacent to a first side of the active area and a second side of the active area crossing the first side of the active area.

8. The display apparatus of claim 1, wherein:
the crack test area includes a plurality of second crack test patterns disposed in the bending area of the display panel.

9. The display apparatus of claim 8, wherein:
the plurality of second crack test patterns includes a protruding portion.

10. The display apparatus of claim 1, wherein:
the crack test area includes a plurality of third crack test patterns disposed adjacent to a hole area in the active area of the display panel.

11. The display apparatus of claim 1, wherein:
the plurality of test points is configured to receive a test voltage, and
wherein when the test voltage is less than a predetermined reference voltage, a crack of the display panel is detected.

12. The display apparatus of claim 1, wherein:
the plurality of test points is configured to receive a test current, and
wherein when the test current is outside a range of a first reference current and a second reference current at a test time point in a determining cycle, a crack of the display panel is detected.

13. The display apparatus of claim 1, wherein:
when a test point of the plurality of test points receives a test signal that does not exceed a reference signal in a determining cycle or exceeds the reference signal two or more times in the determining cycle, a crack of the display panel is detected.

14. The display apparatus of claim 1, wherein:
a crack of the display panel is detected using a test circuit, and
wherein the test circuit includes:
a reference resistor including a first electrode configured to receive a reference signal and a second electrode connected to a first node; and
a transistor including a control electrode configured to receive a test signal from a test point of the plurality of test points, a first electrode connected to the first node, and a second electrode connected to a ground, and
wherein a crack of the display panel is detected based on a signal of the first node.

15. A display apparatus, comprising:
a display panel including an active area configured to display an image, a bending area in which a substrate of the display panel is bent, and a crack test area including a test pattern; and
a driving chip mounted on the substrate,
wherein the substrate comprises a plurality of test points, and
wherein the plurality of test points, the substrate, a portion of the driving chip, the bending area, and the crack test area form a test path.

16. The display apparatus of claim 15, wherein:
the plurality of test points includes a first test point, a second test point, a third test point, and a fourth test point, and
wherein the test path includes:
a first resistor connected to the first test point and corresponding to the substrate of the display panel; a second resistor connected to the first resistor and corresponding to the driving chip;
a third resistor connected to the second test point and corresponding to the substrate of the display panel; a fourth resistor connected to the third resistor and corresponding to the driving chip;
a fifth resistor connected to the third test point and corresponding to the substrate of the display panel; a sixth resistor connected to the fifth resistor and corresponding to the driving chip;
a seventh resistor connected to the fourth test point and corresponding to the substrate of the display panel; an eighth resistor connected to the seventh resistor and corresponding to the driving chip;
a first crack test resistor connected between the second resistor and the fourth resistor and corresponding to the crack test area; a second crack test resistor connected between the fourth resistor and the sixth resistor and corresponding to the crack test area; and a third crack test resistor connected between the sixth resistor and the eighth resistor and corresponding to the crack test area.

17. An electronic device, comprising:
a printed circuit board including a plurality of test points and a first bonding area bonding a flexible circuit board;
a display panel including an active area configured to display an image, a second bonding area bonding the display panel and the flexible circuit board, and a crack test area including a test pattern;
a display panel driver configured to drive the display panel; and
a processor configured to output image data and a control signal to the display panel driver,
wherein the flexible circuit board bonded to the first bonding area of the printed circuit board, and
wherein the plurality of test points, the printed circuit board, the first bonding area, the flexible circuit board, the second bonding area, and the crack test area for a test path.

18. The electronic device of claim 17, wherein:
the plurality of test points includes a first test point, a second test point, a third test point, and a fourth test point, and
wherein the test path includes:
a first resistor connected to the first test point and corresponding to the printed circuit board; a second resistor connected to the first resistor and corresponding to a first adhesive material disposed in the first bonding area; a third resistor connected to the second resistor and corresponding to the flexible circuit board; a fourth resistor connected to the third resistor and corresponding to a second adhesive material disposed in the second bonding area;
a fifth resistor connected to the second test point and corresponding to the printed circuit board; a sixth resistor connected to the fifth resistor and corresponding to a third adhesive material disposed in the first bonding area; a seventh resistor connected to the sixth resistor and corresponding to the flexible circuit board; an eighth resistor connected to the seventh resistor and corresponding to a fourth adhesive material disposed in the second bonding area;
a ninth resistor connected to the third test point and corresponding to the printed circuit board; a tenth resistor connected to the ninth resistor and corresponding to a fifth adhesive material disposed in the first bonding area; an eleventh resistor connected to the tenth resistor and corresponding to the flexible circuit board; a twelfth resistor connected to the eleventh resistor and corresponding to a sixth adhesive material disposed in the second bonding area;
a thirteenth resistor connected to the fourth test point and corresponding to the printed circuit board; a fourteenth resistor connected to the thirteenth resistor and corresponding to a seventh adhesive material disposed in the first bonding area; a fifteenth resistor connected to the fourteenth resistor and corresponding to the flexible circuit board; a sixteenth resistor connected to the fifteenth resistor and corresponding to an eighth adhesive material disposed in the second bonding area;
a first crack test resistor connected between the fourth resistor and the eighth resistor and corresponding to the crack test area; a second crack test resistor connected between the eighth resistor and the twelfth resistor and corresponding to the crack test area; and a third crack test resistor connected between the twelfth resistor and the sixteenth resistor and corresponding to the crack test area.

19. The electronic device of claim 17, wherein:
the plurality of test points includes a first test point, a second test point, a third test point, and a fourth test point, and
wherein a current source is connected to the first test point and the second test point, and a voltmeter is connected to the third test point and the fourth test point.

20. The electronic device of claim 17, wherein:
the plurality of test points includes a first test point, a second test point, a third test point, and a fourth test point, and
wherein an ammeter is connected to the first test point and the second test point, and a voltage source is connected to the third test point and the fourth test point.
